(19) United States
(12) Patent Application Publication
(10) Pub. No.: US 2024/0379347 A1
(43) Pub. Date: Nov. 14, 2024

(54) SELECTIVE DEPOSITION OF A MATERIAL COMPRISING SILICON AND NITROGEN

(71) Applicant: ASM IP Holding B.V., Almere (NL)

(72) Inventors: Mikko Ruoho, Vantaa (FI); Eva E. Tois, Espoo (FI); Viljami J. Pore, Helsinki (FI); Marko Tuominen, Helsinki (FI)

(21) Appl. No.: 18/656,799

(22) Filed: May 7, 2024

Related U.S. Application Data
(60) Provisional application No. 63/500,934, filed on May 9, 2023.

(51) Int. Cl. H01L 21/02; C23C 16/02; C23C 16/34; C23C 16/44; C23C 16/455; C23C 16/50; H01J 37/32

(52) U.S. Cl. CPC H01L 21/0228; C23C 16/02; C23C 16/345; C23C 16/4408; C23C 16/45542; C23C 16/45553; C23C 16/50; H01J 37/32357; H01J 37/3244; H01L 21/02126; H01L 21/0214; H01L 21/02167; H01L 21/0217; H01L 21/02211; H01L 21/02312; H01J 2237/338

(57) ABSTRACT

The present disclosure relates to methods and systems for selectively depositing a material comprising silicon and nitrogen onto a substrate comprising a first surface and a second surface, wherein the deposition occurs on the first surface of the substrate more so than on the second surface of the substrate. More specifically, the methods and systems comprise exposing a substrate that comprises a first surface and a second surface to a source of chlorine and a source of silicon, then exposing the substrate to a source of nitrogen to selectively deposit a material comprising silicon and nitrogen on the first surface of the substrate.

### CROSS-REFERENCE TO RELATED APPLICATION(S)

This application claims the benefit of U.S. Provisional Application 63/500,934 filed on May 9, 2023, the entire contents of which are incorporated herein by reference.

### FIELD

The present disclosure relates to methods and systems for the manufacture of semiconductor devices. More particularly, the disclosure relates to methods and systems for selectively depositing a material comprising silicon and nitrogen on a substrate using a cyclic deposition process.

### BACKGROUND

Films comprising silicon and nitrogen are widely used in the semiconductor industry. For instance, silicon nitride thin films may be used as passivation layers, diffusion barriers, gate insulators, sidewall spacers, trench liners, air gap liners, charge trapping layers, masking layers, and so forth. Such films may be deposited using atomic layer deposition (ALD), and thermal and plasma assisted ALD methods are known. ALD methods typically lead to uniform material deposition over at least the entire lateral surface of a substrate. Subsequent lithography and etch steps may then be utilized to form patterns on the substrate surface to form various semiconductor device structures.

Recently, strategies for selective deposition, in which material may be selectively deposited on certain portions of a substrate and not on other portions of the substrate, have gained attention. Selected deposition methods could potentially reduce the number of lithography and etch steps in semiconductor device manufacturing processes and assist with device miniaturization by enhancing scaling in narrow structures and reducing edge placement errors in multilayer device stacks. Various strategies for selective deposition have been proposed and additional improvements are needed to expand the use of selective deposition to new materials. In this regard, selective deposition methods for films comprising silicon and nitrogen may have a large impact in semiconductor device manufacturing.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An aspect of the present disclosure relates to methods for selectively depositing a thin film of a material comprising silicon and nitrogen on a substrate, comprising: providing a substrate comprising a first surface and a second surface in a reaction space, wherein the first surface and the second surface are chemically distinct; exposing the substrate to a silicon precursor, wherein the silicon precursor adsorbs on the first surface of the substrate more so than on the second surface of the substrate; and exposing the substrate to a nitrogen precursor formed in a remote plasma to convert the adsorbed silicon precursor to a material comprising silicon and nitrogen. In some embodiments, the method further comprises a pretreatment step comprising exposing the substrate to a chlorine pretreatment agent. In other embodiments, the method does not comprise a separate passivation pretreatment step and/or a separate activation pretreatment step. In some embodiments, the method further comprises, purging the reaction space prior to exposing the substrate to the silicon precursor and/or prior to exposing the substrate to the nitrogen precursor formed in the remote plasma. The method may further comprise, sequentially repeating the exposing steps and optionally the purging steps to grow a film of the material comprising silicon and nitrogen having a target thickness on the first surface of the substrate.

Another aspect of the present disclosure relates to systems, for example, a semiconductor processing apparatus, comprising: a reaction space for accommodating a substrate comprising a first surface and a second surface, wherein the first surface and the second surface are chemically distinct; a first source for providing a silicon precursor in gas communication via a first valve with the reaction space; a second source for providing a reactive gas in gas communication via a second valve with the reaction space; a remote plasma unit comprising a plasma generator; and a controller operably connected to the first valve, the second valve, and the plasma generator. The controller is configured and programmed to control: supplying the silicon precursor into the reaction space, wherein the silicon precursor adsorbs on the first surface of the substrate more so than on the second surface of the substrate; and supplying the reactive gas into the reaction space and activating the plasma generator to form a nitrogen precursor, wherein the nitrogen precursor converts the adsorbed silicon precursor to a material comprising silicon and nitrogen. In some embodiments, the system further comprises a third source for providing a chlorine pretreatment agent in gas communication via a third valve with the reaction space; the controller is operably connected to the third value and is configured and programmed to control supplying the chlorine pretreatment agent into the reaction space. In some embodiments, the controller is further programmed to sequentially repeat the supplying of the silicon precursor, the supplying of the reactive gas and the activating of the plasma generator, and optionally the supplying of the chlorine pretreatment agent to grow a film of the material comprising silicon and nitrogen having a target thickness on the first surface of the substrate.

In these aspects, in some embodiments, the material comprising silicon and nitrogen is deposited on the first surface of the substrate and not substantially on the second surface of the substrate. In some embodiments, the material comprising silicon and nitrogen is deposited on the first surface of the substrate and not on the second surface of the substrate. In some embodiments, the second surface is substantially free of the material comprising silicon and nitrogen. In some embodiments, the second surface is free of the material comprising silicon and nitrogen.

In these aspects, in some embodiments, a ratio of the material comprising silicon and nitrogen deposited on the first surface of the substrate versus the second surface of the substrate is at least about 70:30. In some embodiments, the ratio is at least about 80:20. In some embodiments, the ratio is at least about 90:10. In some embodiments, the ratio is at least about 95:5. In some embodiments, the ratio is at least about 98:2. In some embodiments, the ratio is at least about 99:1. In some embodiments, the ratio is at least about 99.5:0.5. In some embodiments, the ratio is at least about 99.9:0.1.

In these aspects, in some embodiments, the material comprising silicon and nitrogen is selected from the group consisting of silicon nitride, silicon carbonitride, silicon oxynitride, silicon carbon oxynitride, and combinations thereof. In some embodiments, the material comprising silicon and nitrogen is silicon nitride.

In these aspects, in some embodiments, the first surface of the substrate is selected from the group consisting of silicon nitride, a transition metal oxide, and combinations thereof. In some embodiments, the first surface comprises silicon nitride. In other embodiments, the first surface comprises a transition metal oxide. The transition metal oxide may be a group 4 transition metal oxide. The transition metal oxide may be selected from the group consisting of hafnium oxide, zirconium oxide, and a combination thereof.

In these aspects, in some embodiments, the second surface of the substrate is selected from the group consisting of silicon, silicon oxide, and a metal. In some embodiments, the second surface comprises silicon. In some embodiments, the second surface comprises silicon oxide. In other embodiments, the second surface comprises a metal. The metal may be a transition metal. The metal may be selected from the group consisting of copper, tungsten, ruthenium, cobalt, aluminum, molybdenum, niobium, nickel, manganese, iron, zinc, tantalum, titanium, and combinations thereof. Typically, the metal may be selected from the group consisting of copper, tungsten, ruthenium, cobalt, and combinations thereof.

In these aspects, in some embodiments, the first surface of the substrate comprises silicon nitride and the second surface of the substrate comprises one or more of silicon, silicon oxide, and a metal. In some embodiments, the first surface comprises silicon nitride and the second surface comprises silicon. In some embodiments, the first surface comprises silicon nitride and the second surface comprises silicon oxide. In other embodiments, the first surface comprises silicon nitride and the second surface comprises a metal. The metal may be a transition metal. The metal may be selected from the group consisting of copper, tungsten, ruthenium, cobalt, aluminum, molybdenum, niobium, nickel, manganese, iron, zinc, tantalum, titanium, and combinations thereof. Typically, the metal may be selected from the group consisting of copper, tungsten, ruthenium, cobalt, and combinations thereof.

In these aspects, in some embodiments, the first surface of the substrate comprises a transition metal oxide and the second surface of the substrate comprises one or more of silicon, silicon oxide, and a metal. In some embodiments, the first surface comprises a transition metal oxide and the second surface comprises silicon. In some embodiments, the first surface comprises a transition metal oxide and the second surface comprises silicon oxide. In other embodiments, the first surface comprises a transition metal oxide and the second surface comprises a metal. The metal may be a transition metal. The metal may be selected from the group consisting of copper, tungsten, ruthenium, cobalt, aluminum, molybdenum, niobium, nickel, manganese, iron, zinc, tantalum, titanium, and combinations thereof. Typically, the metal may be selected from the group consisting of copper, tungsten, ruthenium, cobalt, and combinations thereof.

In these aspects, in some embodiments, the first surface of the substrate comprises hafnium oxide and the second surface of the substrate comprises one or more of silicon, silicon oxide, and a metal. In some embodiments, the first surface comprises hafnium oxide and the second surface comprises silicon. In some embodiments, the first surface comprises hafnium oxide and the second surface comprises silicon oxide. In other embodiments, the first surface comprises hafnium oxide and the second surface comprises a metal. The metal may be a transition metal. The metal may be selected from the group consisting of copper, tungsten, ruthenium, cobalt, aluminum, molybdenum, niobium, nickel, manganese, iron, zinc, tantalum, titanium, and combinations thereof. Typically, the metal may be selected from the group consisting of copper, tungsten, ruthenium, cobalt, and combinations thereof.

In these aspects, in some embodiments, the first surface of the substrate comprises zirconium oxide and the second surface of the substrate comprises one or more of silicon, silicon oxide, and a metal. In some embodiments, the first surface comprises zirconium oxide and the second surface comprises silicon. In some embodiments, the first surface comprises zirconium oxide and the second surface comprises silicon oxide. In other embodiments, the first surface comprises zirconium oxide and the second surface comprises a metal. The metal may be a transition metal. The metal may be selected from the group consisting of copper, tungsten, ruthenium, cobalt, aluminum, molybdenum, niobium, nickel, manganese, iron, zinc, tantalum, titanium, and combinations thereof. Typically, the metal may be selected from the group consisting of copper, tungsten, ruthenium, cobalt, and combinations thereof.

In these aspects, in some embodiments, the silicon precursor comprises silicon and chlorine. In some embodiments, the silicon precursor is selected from the group consisting of a chlorosilane, an alkyl chlorosilane, and combinations thereof. In some embodiments, the silicon precursor is selected from the group consisting of dichlorosilane, tetrachlorosilane, hexachlorodisilane, octachlorotrisilane, bis(trichlorosilyl) methane, bis(trichlorosilyl) ethane, and combinations thereof.

In these aspects, in some embodiments, the silicon precursor possesses dual functionality, adsorbing on the first surface of the substrate and pacifying the second surface of the substrate. In some embodiments, the substrate is not exposed to a separate passivation agent and/or a separate activation agent.

In these aspects, in some embodiments, the substrate is exposed to a chlorine pretreatment agent. The chorine pretreatment agent may be selected from the group consisting of chlorine gas (Cl₂), hydrochloric acid (HCl), carbon tetrachloride (CCl₄), chloroform (CHCl₃), dichloromethane (CH₂Cl₂), silicon chloride (SiCl₄), silicon trichloride (SiHCl₃), silicon dichloride (SiH₂Cl₂), phosphorous pentachloride (PCl₅), calcium chloride (CaCl₂)), sodium chloride (NaCl), magnesium (MgCl₂), tungsten chloride (WCl₂), iron chloride (FeCl₃), and combinations thereof.

In these aspects, in some embodiments, the nitrogen precursor is a nitrogen plasma species that is free of ions and electrons. In some embodiments, the nitrogen precursor is selected from the group consisting of activated nitrogen, activated ammonia, nitrogen atoms, NH radicals, NH₂ radicals, and combinations thereof.

In these aspects, in some embodiments, the remote plasma is spatially separated from the substrate. In some embodiments, the remote plasma discharge is formed in an upper portion of the reaction space, and the substrate is located in a lower portion of the reaction space. In some embodiments, an ion trap is provided between the remote plasma discharge and the substrate. The ion trap may be an electrically grounded mesh plate. In other embodiments, the remote plasma discharge is formed in a remote plasma unit.

### BRIEF DESCRIPTION OF DRAWINGS

The accompanying drawings constitute part of the specification. The drawings are included to provide a further understanding of the disclosure, and together with the description explain certain principles of the disclosure. The drawings illustrate exemplary embodiments of how the disclosure can be made and used and are not to be construed as limiting the disclosure to only the illustrated and described examples. It will be appreciated that elements in the figures are illustrated for simplicity and clarity and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure. Further features and advantages will become apparent from the following, more detailed, description of various aspects, embodiments, and configurations of the disclosure, as illustrated by the drawings referenced below.

FIG. 1 is a process diagram of an exemplary embodiment of the disclosure, wherein the process comprises contacting a substrate with a chlorine source and a silicon source 101, then contacting the substrate with a nitrogen source 103. Other optional steps are shown by the dashed lines.

FIG. 2 is a process diagram of an exemplary embodiment of the disclosure, wherein the process comprises optionally contacting a substrate with a chlorine source 201, contacting a substrate with a chlorine source and a silicon source 203, then contacting the substrate with a nitrogen source 205. Other optional steps are shown by the dashed lines.

FIG. 3 is a process diagram of an exemplary embodiment of the disclosure, wherein the process comprises contacting a substrate with a chlorine source 301, contacting the substrate with a silicon source 303, then contacting the substrate with a nitrogen source 305. Other optional steps are shown by the dashed lines.

FIG. 4A, FIG. 4B, and FIG. 4C show representative pulse schemes for the chlorine pretreatment agent, the silicon precursor, the nitrogen compound/precursor, and the remote plasma discharge for three exemplary embodiments of the disclosure. FIG. 4A shows an example of pulse sequences for the silicon precursor, the nitrogen compound/precursor, and the remote plasma discharge. FIG. 4B shows an example of pulse sequences for the chlorine pretreatment agent, the silicon precursor, the nitrogen compound/precursor, and the remote plasma, where m n. FIG. 4C shows an example of pulse sequences for the chlorine pretreatment agent, the silicon precursor, the nitrogen compound/precursor, and the remote plasma discharge, where m n.

FIG. 5 is a schematic presentation of a semiconductor processing apparatus 500 according to an embodiment of the present disclosure.

FIG. 6 shows the thickness of a silicon nitride film as a function repeated ALD cycles (n) on a substrate, each ALD cycle comprises dosing a silicon precursor into the reaction chamber, purging, dosing a N₂/H₂/Ar/He remote plasma into the reaction chamber, and purging. The filled triangle symbols (▴) show the film growth on a silicon nitride surface at 390° C. using bis(trichlorosilyl) methane; the filled circle symbols (●) show the film growth on a silicon nitride surface at 390° C. using bis(trichlorosilyl) ethane; the open triangle symbol (Δ) shows the film growth on a native oxide terminated silicon surface at 390° C. using bis(trichlorosilyl) methane; and the open circle symbol (∘) shows the film growth on a native oxide terminated silicon surface at 390° C. using bis(trichlorosilyl) ethane.

FIG. 7A and FIG. 7B show the thickness of a silicon nitride film as a function of ALD cycles (n) on a substrate at 350° C., each ALD cycle comprises dosing octachlorotrisilane into the reaction chamber, purging, dosing a N₂/H₂/Ar/He plasma into the reaction chamber, and purging. The filled triangle symbols (▴) show the film growth on a silicon nitride surface using a remote plasma; the closed square symbols (▪) show the film growth on a native oxide terminated silicon surface using a remote plasma; and the closed circle symbols (●) show the film growth on a native oxide terminated silicon surface using a direct plasma. In FIG. 7B the y-axis is expanded to better show the data.

### DETAILED DESCRIPTION

The description of embodiments of methods and systems provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. Unless otherwise noted, the exemplary embodiments or components thereof may be combined or may be applied separate from each other. The headings provided herein, if any, are for convenience only and do not necessarily affect the scope or meaning of the claimed invention.

### Definitions

As used herein, an “activation agent” refers to a compound that promotes, excites, or otherwise activates a material in which it interacts with, through a chemical or physical reaction, making the material more likely to decompose or react with itself and/or other materials. Such interaction of an activation agent with a material may be referred to as an “activation step”.

As used herein, “adsorption” refers to a process in which atoms, ions, or molecules attach to the surface of a material. Adsorption may occur through physisorption (i.e., via Vander walls forces), chemisorption (i.e., via covalent bonds), or electrostatic interaction. The attached atoms, ions, or molecules are “absorbed” on the surface of the substrate.

As used herein, “atomic layer deposition”, abbreviated as “ALD”, refers to a vapor deposition process in which deposition cycles, such as a plurality of consecutive deposition cycles, are conducted in a reaction space (i.e., one or more reaction chambers). Generally, in ALD processes, during each cycle, a precursor is introduced to a reaction space and is adsorbed onto a substrate surface, which may include a previously deposited material from a previous ALD cycle or other materials, forming maximally one monolayer of the precursor and/or fragment(s) of the precursor that does not readily react with additional excess precursor (i.e., a self-limiting reaction). Thereafter, in some cases, another precursor or a reactant may be introduced into the reaction space for use in converting the adsorbed precursor to the desired material on the substrate surface. ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “cyclical deposition process” or “cyclical deposition method” refers to a method or a process comprising sequentially introducing reactants into a reaction space to deposit a layer or a film over a substrate and includes processing techniques such as ALD.

As used herein, a “film” or a “layer”, which may be used interchangeably, refers to a continuous, substantially continuous, or non-continuous material that extends in a direction perpendicular to a thickness direction to cover at least a portion of a surface. A film can include two-dimensional materials, three-dimensional materials, nanoparticles, or even partial or full molecular layers, or partial or full atomic layers, and/or clusters of atoms or molecules. A film may be built up from one or more non-discernable layers (e.g., monolayers or sub-monolayers) to produce a uniform, or a substantially uniform material, wherein the number of layers influences the thickness of the material.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein. “hafnium oxide” or “HfOₓ” refers to a material that comprises Hf—O bonds. Hafnium oxide can be represented by the formula HfOₓ, where x ranges from about 0.5 to about 2.5, typically x is about 2. It will be understood that x may vary depending on the specific precursor(s) and process conditions chosen for the deposition process, among other factors, and may not be stochiometric. In some instances, the hafnium oxide can include other elements, such as carbon, nitrogen, and/or hydrogen. In some embodiments, the hafnium oxide may be represented by the formula HfO₂. In some embodiments, the hafnium oxide comprises HfO₂. In some embodiments, the hafnium oxide consists, or consists essentially, of HfO₂.

As used herein, a “passivation agent” refers to a compound that deactivates, inhibits, blocks, or otherwise passivates a material in which it interacts with, through a chemical or physical reaction, making the material less prone to decompose or react with itself and/or other materials. Such interaction of a passivation agent with a material may be referred to as a “passivation step”.

As used herein, a “plasma” refers to an ionized gas comprising of roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide different fluxes of the various species.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, “silicon carbonitride” or “SiCN” refers to a material that comprises Si—N bonds and Si—C bonds. Silicon carbonitride can be represented by the formula Si_{w}CₓN_{y} where w can range from about 0.5 to about 2.5, x can range from about 0 to about 2.5, and y can range from about 0.5 to about 4.5. It will be understood that the variables w, x, and y may vary depending on the specific precursor(s) and process conditions chosen for the deposition process, among other factors, and may not be stochiometric. In some cases, the silicon carbonitride may include other elements, such as oxygen and/or hydrogen. In some embodiments, the silicon carbonitride may comprise silicon carbide and silicon nitride.

As used herein, “silicon carbon oxynitride” or “SiOCN” refers to a material that comprises Si—O bonds, Si—N bonds, and Si—C bonds. Silicon carbon oxynitride can be represented by the formula Si_{w}OₓC_{y}N_{z}, where w can range from about 0.5 to about 2.5, x can range from about 0 to about 2.5, y can range from about 0 to about 2.5, and z can range from about 0.5 to about 4.5. It will be understood that the variables w, x, y, and z may vary depending on the specific precursor(s) and process conditions chosen for the deposition process, among other factors, and may not be stochiometric. In some cases, the silicon carbon oxynitride may comprise other elements, such as hydrogen.

As used herein, “silicon nitride” or “SiN” refers to a material that comprises Si—N bonds. In some embodiments, the silicon nitride may be represented by the formula Si_{y}Nₓ, where y can range from about 0.5 to about 3.5 and x can range from about 0.5 to about 4.5, typically y is about 3 and x is about 4. It will be understood that the variables y and x may vary depending on the specific precursor(s) and process conditions chosen for the deposition process, among other factors, and may not be stochiometric. In some cases, the silicon nitride may include other elements, such as carbon, oxygen, and/or hydrogen. In some embodiments, the silicon nitride may be represented by the formula Si₃N₄. In some embodiments, the silicon nitride comprises Si₃N₄. In some embodiments, the silicon nitride consists, or consists essentially, of Si₃N₄.

As used herein, “silicon oxide” or “SiOₓ” refers to a material that comprises Si—O bonds. Silicon oxide can be represented by the formula SiOₓ, where x ranges from about 0.5 to about 2.5, typically x is about 2. It will be understood that the variable x may vary depending on the specific precursor(s) and process conditions chosen for the deposition process, among other factors, and may not be stochiometric. In some instances, the silicon oxide can include other elements, such as carbon, nitrogen, and/or hydrogen. In some embodiments, the silicon oxide may be represented by the formula SiO₂. In some embodiments, the silicon oxide comprises SiO₂. In some embodiments, the silicon oxide consists, or consists essentially, of SiO₂.

As used herein, “silicon oxynitride” or “SiON” refers to a material that comprises Si—O bonds and Si—N bonds. Silicon oxynitride can be represented by the formula Si_{w}OₓN_{y} where w can range from about 0.5 to about 2.5, x can range from about 0 to about 2.5, and y can range from about 0 to about 4. It will be understood that the variables w, x, and y may vary depending on the specific precursor(s) and process conditions chosen for the deposition process, among other factors, and may not be stochiometric. In some cases, the silicon oxynitride may comprise other elements, such as carbon and/or hydrogen. In some embodiments, the silicon oxynitride may include silicon oxide and silicon nitride. In some embodiments, the silicon oxynitride may be represented by the formula Si₂N₃O. In some embodiments, the silicon oxynitride comprises Si₂N₃P. In some embodiments, the silicon oxynitride consists, or consists essentially, of Si₂N₃O.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as a powder, a plate, or a workpiece. Substrates in the form a sheet may extend beyond the bounds of a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, silicon, silicon germanium, silicon oxide, gallium arsenide, gallium nitride, and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. The substrate can include various topologies, such as gaps, including vias, recesses, lines, trenches, or spaces between elevated portions, such as fins, and the like formed within or on at least a portion of a layer of the substrate.

As used herein, “zirconium oxide” or “ZrOₓ” refers to a material that comprises Zr—O bonds. Zirconium oxide can be represented by the formula ZrOₓ, where x ranges from about 0.5 to about 2.5, typically x is about 2. It will be understood that x may vary depending on the specific precursor(s) and process conditions chosen for the deposition process, among other factors, and may not be stochiometric. In some instances, the zirconium oxide can include other elements, such as carbon, nitrogen, and/or hydrogen. In some embodiments, the zirconium oxide may be represented by the formula ZrO₂. In some embodiments, the zirconium oxide comprises ZrO₂. In some embodiments, the zirconium oxide consists, or consists essentially, of ZrO₂.

Articles “a” or “an” refer to a species or a genus including multiple species, depending on the context. As such, the terms “a/an”, “one or more”, and “at least one” can be used interchangeably herein.

The terms “comprising”, “including”, and “having” are open ended and do not exclude the presence of other elements or components, unless the context clearly indicates otherwise. “Comprising,” “including,” and “having” can be used interchangeably and include the meaning of “consisting of”. The phrase “consisting of”, however, indicates that no other features or components are present other than those mentioned, unless the context indicates otherwise.

The term “about” as applied to a value generally refers to a range of numbers that is considered equivalent to the recited value (e.g., having the same function or result). In some instances, the term about may include numbers that are rounded to the nearest significant figure.

The term “essentially” as applied to a composition, a method, or a system generally means that the additional components do not substantially modify the properties and/or function of the composition, the method, or the system.

The term “substantially” as applied to a composition, a method, or a system generally refers to a proportion of at least about 70%, or at least about 80%, or at least about 90%, or at least about 95%, or at least about 97%, or at least about 98%, or at least about 99%, or at least about 99.5%, or at least about 99.9%, or more, or any proportion between about 70% and about 100%. In some embodiments, the term “substantially” means a proportion of about 90%, or about 95%, or about 97%, or about 98%, or about 99%, or about 99.5%, or about 99.9%.

The terms “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Z₁).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

In certain places throughout the disclosure, a chemical compound, a functional group of a chemical compound, or a substituent or ligand may be referred to by a chemical name (e.g., an IUPAC name or a common name), a molecular formula which may be abbreviated, or both. In cases where there is a conflict between the chemical name and the molecular formula, and the identity of the chemical compound, the functional group, or the substituent or ligand cannot be unambiguously ascertained by one of skill in the art, then the molecular formula shall prevail.

The present disclosure generally relates to methods and systems for selectively depositing a thin film of a material comprising silicon and nitrogen on a surface of a substrate. More specifically, the present disclosure generally relates to methods and systems for selectively depositing a thin film of a material comprising silicon and nitrogen on a first surface of a substrate more so than on a second surface of a substrate. The methods and systems for selectively depositing a thin film of a material comprising silicon and nitrogen may be used in a variety of applications in the semiconductor industry, such as, in the manufacture of memory and/or logic devices. Various aspects of the methods and the systems and the benefits derived therefrom will now be described.

Selective atomic layer deposition is achieved by exploiting differences in the reactivities of various surface sites on a substrate to yield deposition on certain sites but not on other sites. In this regard, the inventors have found that certain chemical reactants, or a combination of chemical reactants, comprising chlorine and silicon can advantageously lead to the adsorption of a silicon-containing material on some surface sites more so than on other surface sites of a substrate. The substrate is then exposed to a nitrogen precursor that is formed in a remote plasma to convert the adsorbed silicon-containing material to a material comprising silicon and nitrogen. The disclosed methods and systems can beneficially allow for a thin film of a material comprising silicon and nitrogen to be formed predominantly or exclusively on targeted areas of a substrate surface. For example, in some embodiments, using the methods and systems disclosed herein, a silicon nitride thin film may be selectively deposited on a silicon nitride surface but not on a silicon oxide surface. Such selective deposition may be useful in the formation of high aspect ratio features in devices for memory applications. For instance, in one example, silicon nitride may be selectively deposited on the sidewalls but not on the bottom of trenches thereby increasing the aspect ratio of the of the structure.

As used herein, a material comprising silicon and nitrogen may refer to silicon nitride, silicon carbonitride, silicon oxynitride, silicon carbon oxynitride, and combinations thereof. In some embodiments, the material comprising silicon and nitrogen is silicon nitride. In some embodiments, the material comprises silicon and nitrogen and may comprise other elements, such as one or more of hydrogen, carbon, and oxygen, among others, to various extents. In some embodiments, the material predominantly comprises silicon and nitrogen and may contain lesser amounts of other elements, such as one or more of hydrogen, carbon, and oxygen, among others. In some embodiments, the material consists of or consists essentially of silicon and nitrogen.

An aspect of the present disclosure relates to methods for selectively depositing a thin film of a material comprising silicon and nitrogen on a first surface of a substrate more so than on a second surface of the substrate using a cyclic deposition process. The first and second surfaces are chemically distinct to provide contrast for the selective deposition. The methods comprise, providing a substrate comprising a first surface and a second surface in a reaction space (i.e., one or more reaction chambers) and exposing the substrate to a source of chlorine and a source of silicon. In some embodiments, the substrate is exposed to a silicon precursor that comprises both silicon and chlorine (i.e., a source of silicon and a source of chlorine). In other embodiments, the substrate is exposed to a chlorine pretreatment agent (i.e., a source of chlorine) and to a silicon precursor that comprises silicon and optionally chlorine (i.e., a source of silicon and an optional source of chlorine). In either of these embodiments, the silicon precursor absorbs, forming maximally one monolayer, on the first surface of the substrate. Less, substantially less, or none of the silicon precursor absorbs onto the second surface of the substrate. Without wishing to be bound by a particular theory, it is hypothesized that the selective adsorption of the silicon precursor occurs because the chlorine in the chlorine source deactivates, blocks, inhibits, and/or otherwise passivates the second surface sites on the substrate so that they are less prone or unavailable to absorb the silicon precursor. Next, the substrate is exposed to a nitrogen precursor (i.e., a source of nitrogen) that is generated in a remote plasma. The various steps are repeated, as necessary, to selectively deposit a film of the material comprising silicon and nitrogen having a targeted thickness on the first surface of the substrate. Exemplary embodiments as well as individual process steps and elements will be described in more detail below.

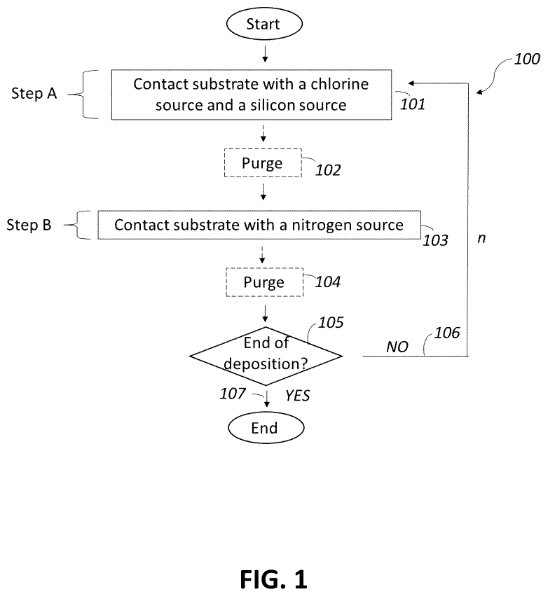

FIG. 1 is a process flow diagram 100 of an exemplary embodiment of the disclosure. The process comprises: providing a substrate comprising a first surface and a second surface in a reaction space; exposing the substrate to a silicon precursor that comprises silicon and chlorine (i.e., a source of chlorine and a source of silicon) 101, wherein the silicon precursor adsorbs on the first surface of the substrate more so than on the second surface of the substrate; and exposing the substrate to a nitrogen precursor (i.e., a source of nitrogen) that is formed using a remote plasma 103 to convert the adsorbed silicon precursor to a material comprising silicon and nitrogen. Steps 101 and 103 may each be referred to as a half cycle and together they define a cycle. Each half-cycle may be sequentially repeated (n times) 106 to selectively grow a film of the material comprising silicon and nitrogen on the first surface of the substrate. The reaction space may optionally be purged in between each of the two half cycles and/or after a cycle, as shown in blocks 102 and 104. Once the material comprising silicon and nitrogen has reached a targeted thickness on the first surface of the substrate, the process may be terminated 106.

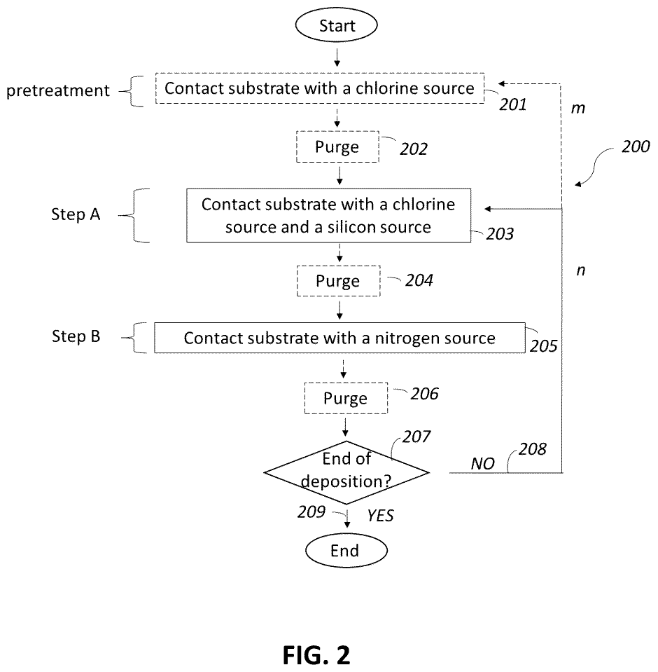

FIG. 2 is a process flow diagram 200 of another exemplary embodiment of the disclosure. The process comprises: providing a substrate comprising a first surface and a second surface in a reaction space; optionally exposing the substrate to a chlorine pretreatment agent (i.e., a source of chlorine) 201; exposing the substrate to a silicon precursor that comprises silicon and chlorine (i.e., a source of chlorine and a source of silicon) 203, wherein the silicon precursor adsorbs on the first surface of the substrate more so than on the second surface of the substrate; and exposing the substrate to a nitrogen precursor (i.e., a source of nitrogen) that is formed using a remote plasma 205 to convert the adsorbed silicon precursor to a material comprising silicon and nitrogen. Steps 203 and 205 may each be referred to as a half cycle and together they define a cycle. Each half-cycle may be sequentially repeated (n times) 208 to selectively grow a film of the material comprising silicon and nitrogen on the first surface of the substrate. The pretreatment step 201 may optionally be repeated (m times) prior to every cycle or intermittently to inhibit growth of the material comprising silicon and nitrogen on the second surface of the substrate. The reaction space may be optionally purged after the optional pretreatment step, if applicable, and/or each of the two half cycles, and/or after a cycle, as shown in blocks 202, 204, and 206. Once the material comprising silicon and nitrogen has reached a targeted thickness on the first surface of the substrate, the process may be terminated 209.

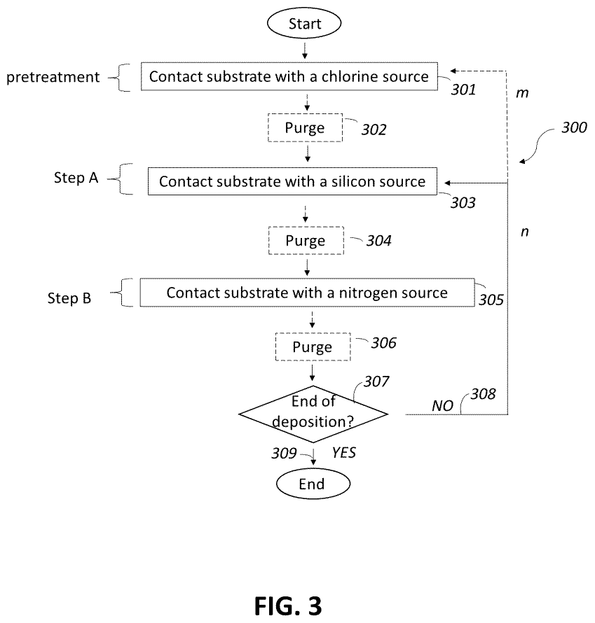

FIG. 3 is a process flow diagram 300 of yet another exemplary embodiment of the disclosure. The process comprises: providing a substrate comprising a first surface and a second surface in a reaction space; exposing the substrate to a chlorine pretreatment agent (i.e., a source of chlorine) 301; exposing the substrate to a silicon precursor that comprises silicon (i.e., a source of silicon) but does not comprise chlorine 303, wherein the silicon precursor adsorbs on the first surface of the substrate more so than on the second surface of the substrate; and exposing the substrate to a nitrogen precursor (i.e., a source of nitrogen) that is formed using a remote plasma 305 to convert the adsorbed silicon precursor to a material comprising silicon and nitrogen. Steps 303 and 305 may each be referred to as a half cycle and together they define a cycle. Each half-cycle may be sequentially repeated (n times) 308 to selectively grow a film of the material comprising silicon and nitrogen on the first surface of the substrate. The pretreatment step 301 may optionally be repeated (m times) prior to every cycle or intermittently to inhibit growth of the material comprising silicon and nitrogen on the second surface of the substrate. The reaction space may be optionally purged after the pretreatment step, and/or after each of the two half cycles, and/or after a cycle, as shown in blocks 302, 304, and 306. Once the material comprising silicon and nitrogen has reached a targeted thickness on the first surface of the substrate, the process may be terminated 309.

In the methods disclosed herein, a substrate comprising a first surface and a second surface is exposed to a source of chlorine and a source of silicon. In some embodiments, exposure of the substrate to the source of chlorine and the source of silicon occurs as a single process step. For example, the method may comprise exposing the substrate to a silicon precursor that comprises silicon and chlorine (e.g., 101 in FIG. 1). In some these embodiments, the substrate is exposed to a single source of chlorine and silicon, and it is not exposed to a separate source of chorine in a separate process step. In other embodiments, exposure of the substrate to the source of chlorine and the source of silicon occurs as a combination of steps. For example, the method may comprise exposing the substrate to a chlorine pretreatment agent and to a silicon precursor that comprises silicon and chlorine (e.g., 201 and 203 in FIG. 2). In yet other embodiments, exposure of the substrate to the source of chlorine and the source of silicon occurs as two distinct process steps. For example, the method may comprise exposing the substrate to a chlorine pretreatment agent and then to a silicon precursor that comprises silicon but not chlorine (e.g., 301 and 303 in FIG. 3). In these embodiments, the various process steps may independently be repeated, as needed, along with other optional process steps, to grow a film of the material comprising silicon and nitrogen on the first surface of the substrate. Furthermore, it will readily be understood by those skilled in the art that certain process steps of the embodiments shown in FIG. 1, FIG. 2, and FIG. 3 may be combined to obtain other embodiments of the disclosed methods.

In certain embodiments where the silicon precursor comprises both silicon and chlorine, the precursor is hypothesized to have dual functionality, beneficially acting as an adsorbent on the first surface of the substrate and a passivation agent towards the second surface of the substrate. Regardless of the underlying mechanism, the silicon precursor adsorbs, forming maximally one monolayer that comprises the silicon precursor and/or fragment(s) of the silicon precursor on the first surface of the substrate and less, substantially less, or none of the silicon precursor adsorbs on the second surface of the substrate. Preferably, the silicon precursor adsorbs, forming maximally one monolayer, on the first surface of the substrate but does not adsorb on the second surface of the substrate. The absorbed silicon precursor may then be converted to a material comprising silicon and nitrogen that is selectively deposited on the first surface of the substrate. Thus, in certain embodiments, the disclosed methods beneficially provide for selective deposition of a material comprising silicon and nitrogen without the use of a separate passivation step and/or a separate activation step (i.e., pretreatment steps). In certain other embodiments, the method may further comprise a separate pretreatment step of exposing the substrate to a chlorine pretreatment agent; however, because of the dual functionality of the silicon precursor, the number of times that the pretreatment step needs to be repeated during the deposition process may be minimized.

In embodiments, the silicon precursor is introduced or pulsed into the reaction space where it interacts with the substrate surface(s). Preferably, the silicon precursor is in gaseous form, or it has sufficient vapor pressure at or near room temperature, or slightly above room temperature, so that it is easily transported into the reaction space and to the substrate surface(s). The silicon precursor may be heated to increase its vapor pressure and/or it may be entrained in a flow of an inert carrier gas (e.g., nitrogen and/or a noble gas such as helium (He) and argon (Ar)) and introduced into the reaction space.

A number of suitable silicon precursors can be used in the disclosed selective deposition methods. The silicon precursor comprises silicon and may further comprise one or more of chlorine (Cl), hydrogen (H), carbon (C), nitrogen (N), oxygen (O), and a halogen atom other than chlorine (e.g., bromine (Br) and/or iodine (I)). In certain embodiments, the silicon precursor comprises silicon and chlorine and may further comprise one or more of hydrogen, carbon, nitrogen, oxygen, and a halogen atom other than chlorine (i.e., Br, and/or I). The silicon precursor may comprise one or more of Si—Si bond(s), Si—Cl bond(s), Si—H bond(s), Si—C bond(s), Si—N bond(s), Si—O bond(s), Si—I bond(s), and Si—Br bond(s).

In some embodiments, the silicon precursor is selected from the group consisting of a silane, a halosilane, an organosilane, a silylamine, a silazane, a siloxane, and combinations thereof, each of which, in certain embodiments, may be substituted with a chlorine atom. In some embodiments, the silicon precursor is an inorganic silane, such as silane or a halosilane, and in certain embodiments, the silicon precursor is a chlorosilane. An inorganic silane may comprise one silicon atom, two silicon atoms (i.e., a disilane), three silicon atoms (i.e., a trisilane), or more, and may also comprise one or more hydrogen atoms and halogen atoms (X) (where X═Cl, Br, and/or I). Linear and branched inorganic silane compounds may have the following general formula: H_{(2n+2-y)} SiₙX_{y}, where n is an integer from 1 to 10, preferably from 1 to 5, or more preferably from 1 to 3; y is an integer from 0 to 2n+2; and X may independently be selected from Cl, Br, and I, and in certain embodiments, X is Cl. Cyclic inorganic silane compounds may have the following general formula: H_{(2n-y)} SiₙX_{y}, where n is an integer from 3 to 10, preferably from 3 to 6; y is an integer from 0 to 2n; and X may independently be selected from Cl, Br, and I, and in certain embodiments, X is Cl. In some embodiments, the silicon precursor is a chlorosilane compound. Exemplary chlorosilane compounds include, but are not limited to, tetrachlorosilane (SiCl₄), trichlorosilane (HSiCl₃), dichlorosilane (H₂SiCl₂), chlorosilane (H₃SiCl), hexachlorodisilane (Si₂Cl₆), pentachlorodisilane (HSi₂Cl₅), tetrachlorodisilane (H₂Si₂Cl₄), trichlorodisilane (H₃Si₂Cl₃), dichlorodisilane (H₄Si₂Cl₂), chlorodisilane (H₅Si₂Cl), chlorotrisilane (H₇Si₃Cl), dichlorotrisilane (H₆Si₃Cl₂), trichlorotrisilane (H₅Si₃Cl₃), tetrachlorotrisilane (H₄Si₃Cl₄), pentachlorotrisilane (H₃Si₃Cl₅), hexachlorotrisilane (H₂Si₃Cl₆), heptachlorotrisilane (HSi₃Cl₇), octachlorotrisilane (Si₃Cl₈), and combinations thereof.

In some embodiments, the silicon precursor is an organosilane or a silylamine may comprise one silicon atom, two silicon atoms (i.e., a disilane), three silicon atoms (i.e., a trisilane), or more silicon atoms bonded to each other, and may also comprise one or more carbon atoms, nitrogen atoms, hydrogen atoms, and halogen atoms (X) (where X═Cl, Br, and/or I). Such linear and branched organosilane and silylamine compounds may have the following general formula: R_{(2n+2-y)} SiₙX_{y}, where n is an integer from 1 to 10, preferably from 1 to 3, or equal to 1 or 2; y is an integer from 0 to 2n+1; and X is bonded directly to a silicon atom (Si—X) and may independently be selected from Cl, Br, and I, and in certain embodiments, X is Cl. The group R is independently selected from an H atom, an organic ligand, and an amino ligand, but at least one R group is an organic ligand or an amino ligand. For example, at least one R group may be selected from an alkyl group, a substituted alkyl group, an alkenyl group, an aryl group, an alkyloxide, an alkylsilyl, an amine, an alkylamine, and combinations thereof. Preferably, at least one R is selected from an alkyl group, a substituted alkyl group, an amine group, and an alkyl amine group; and in some embodiments, at least one R group is selected from a C₁-C₃ alkyl ligand (e.g., methyl, ethyl, n-propyl, and isopropyl), and a C₁-C₃ substituted alkyl ligand which may comprise one or more chlorine atoms. Such cyclic organosilane and silylamine compounds may have the following general formula: R_{(2n-y)} SiₙX_{y}, where n is an integer from 3 to 10, preferably from 3 to 6; y is an integer from 0 to 2n−1; and X is bonded directly to a silicon atom (Si—X) and may independently be selected from Cl, Br, and I, and in certain embodiments, X is Cl. The group R is independently selected from an H atom, an organic ligand, and an amino ligand, but at least one R group is an organic ligand or an amino ligand. For example, at least one R group may be selected from an alkyl group, a substituted alkyl group, an alkenyl group, an aryl group, an alkyloxide, an alkylsilyl, an amine, an alkylamine, and combinations thereof. Preferably, at least one R group is selected from an alkyl group, a substituted alkyl group, an amine group, and an alkyl amine group; and in some embodiments, at least one R is selected from a C₁-C₃ alkyl ligand (e.g., methyl, ethyl, n-propyl, and isopropyl), and a C₁-C₃ substituted alkyl ligand which may comprise one or more chlorine atoms.

In some embodiments, the silicon precursor is an organosilane, a silazanes, or a siloxane that comprises two silicon atoms, three silicon atoms, or more, and is bonded through a bridge group (i.e., Si-A-Si). Such linear and branched organosilane, silazane, or siloxane compounds may have the following general formula: Si(X_{y}R_{3-y})-A-[Si(X₂R_{2-z})-A]ₙ—Si(X_{y}R_{3-y}), where n is an integer from 0 to 6, preferably from 0 to 3, more preferably 0 or 1; y is an integer from 0 to 3; z is an integer from 0 to 2; and X may independently be selected from Cl, Br, and I, and in certain embodiments X is Cl. The group A is independently selected from an alkenyl, a substituted alkenyl, an amine, a substituted amine, and an oxygen atom; preferably, each A is independently selected from a C₁-C₃ alkylene bridge group (e.g., CH₂, CH₃CH, and CH₃CCH₃), a C₁-C₃ substituted alkenyl group. The group R is independently selected from an H atom and a ligand, such as an alkyl group, a substituted alkyl group, an alkenyl group, an aryl group, an alkyloxides, an amine, an alkylamine, and combinations thereof. Preferably, each R is independently selected from an H atom, an alkyl group, and a substituted alkyl group, and in some embodiments, each R is independently selected from an H atom, a C₁-C₃ alkyl ligand (e.g., methyl, ethyl, n-propyl, or isopropyl), and a C₁-C₃ substituted alkyl ligand which may comprise one or more chlorine atoms. Such cyclic organosilane, silazane, or siloxane compounds may have the following general structure: cy[Si(X_{y}R_{2-y})-A]ₙ, where n is an integer from 3 to 6; y is an integer from 0 to 2; and X may independently be selected from Cl, Br, and I, and in certain embodiments X is Cl. The group A is independently selected from an alkenyl, a substituted alkenyl, an amine, a substituted amine, and an oxygen atom. The group R is independently selected from an H atom and a ligand such as an alkyl group, a substituted alkyl group, an alkenyl group, an aryl group, an alkyloxides, an amine, an alkylamine, and combinations thereof. Preferably, each R is independently selected from an H atom, an alkyl group, and a substituted alkyl group, and in some embodiments, each R is independently selected from an H atom, a C₁-C₃ alkyl ligand (e.g., methyl, ethyl, n-propyl, or isopropyl), and a C₁-C₃ substituted alkyl ligand which may comprise one or more chlorine atoms.

In some embodiments, the silicon precursor is an organochlorosilane compound, preferably an alkylchlorosilane. Exemplary alkylchlorosilane compounds include, but are not limited to, methyltrichlorosilane (SiCH₃Cl₃), dimethyldichlorosilane (Si(CH₃)₂Cl₂), trimethylchlorosilane (Si(CH₃)₃Cl), dichloromethylsilane (HSiCH₃Cl₂), trichloro(dichloromethyl) silane (HCl₂CSiCl₃), trichloro(chloromethyl) silane (H₂ClCSiCl₃), bis(trichlorosilyl) methane (Cl₃SiCH₂SiCl₃), bis(trichlorosilyl) ethane (Cl₃SiCH₂CH₂SiCl₃), and combinations thereof. In preferred embodiments, the silicon precursor is selected from the group consisting of dichlorosilane, tetrachlorosilane, hexachlorodisilane, octachlorotrisilane, bis(trichlorosilyl) methane, bis(trichlorosilyl) ethane, and combinations thereof.

In certain embodiments, the method comprises introducing a chlorine pretreatment agent into the reaction space. The chlorine pretreatment agent is introduced or pulsed into the reaction space where it interacts with the substrate surface(s). Preferably, the chlorine pretreatment agent is in gaseous form, or it has sufficient vapor pressure at or near room temperature, or slightly above room temperature, so that it is easily transported into the reaction space and to the substrate surface(s). The chlorine pretreatment agent may be heated to increase its vapor pressure and/or it may be entrained in a flow of an inert carrier gas (e.g., nitrogen gas and/or a noble gas such as helium (He) and argon (Ar)) and introduced into the reaction space.

The chlorine pretreatment agent comprises chlorine and may further comprise carbon (C), sulfur(S), silicon (Si), phosphorous (P), and a metal (M) (such as, by way of non-limiting example, an alkali metal such as sodium (Na) and potassium (K), an alkaline earth metal such as calcium (Ca) and magnesium (Mg), or a transition metal such as iron (Fe) or tungsten (W)), and combinations thereof. The chlorine pretreatment agent may comprise C—Cl bond(s), S—Cl bond(s), Si-bond(s), P—Cl bond(s), M-Cl bonds, and combinations thereof. In some embodiments, the chlorine pretreatment agent, may comprise silicon and, in these embodiments, the pretreatment agent may not possess dual functionality, meaning that it does not adsorb, or does not substantially adsorb, on the first surface of the substrate; however, it may act to deactivate, block, and/or otherwise passivate the second surface of the substrate. Exemplary chlorine pretreatment agents, include, but are not limited to, chlorine gas (Cl₂), hydrochloric acid (HCl), carbon tetrachloride (CCl₄), chloroform (CHCl₃), dichloromethane (CH₂Cl₂), silicon chloride (SiCl₄), silicon trichloride (SiHCl₃), silicon dichloride (SiH₂Cl₂), phosphorous pentachloride (PCl₅), calcium chloride (CaCl₂)), sodium chloride (NaCl), magnesium (MgCl₂), tungsten chloride (WCl₂), and iron chloride (FeCl₃), and combinations thereof.

The flow rate(s) and/or the pulse duration(s) of the silicon precursor and the chlorine pretreatment agent, if utilized, may be optimized to affect adsorption of the silicon precursor on the first surface of the substrate, while minimizing or preventing adsorption on the second surface of the substrate. Adsorption of the silicon precursor on the first surface is a self-limiting, or a substantially self-limiting, process. Thus, the number of adsorbed silicon precursor molecules on the first surface of the substrate is determined by the number of accessible reactive sites on the first surface and is independent of the exposure time after saturation of the first surface sites has occurred. Excess of the silicon precursor may be supplied into the reaction space to ensure saturation of the first surface sites; however, in some cases, it may be important to limit the amount of excess silicon precursor to minimize or avoid adsorption of the silicon precursor on the second surface sites. Adsorption of the silicon precursor on the second surface sites may be inhibited by exposing the substrate to a source of chlorine, either from the silicon precursor itself, the chlorine pretreatment agent, or both. As such, suitable flow rates and/or pulse times for the silicon precursor may depend on a number of factors, including the nature of the first and second surfaces, the nature of the silicon precursor, and whether the substrate has been exposed to a chlorine pretreatment agent. Optimal flow rates and/or pulsing times for the silicon precursor and the chlorine pretreatment agent, if utilized, can be determined by the skilled artisan to affect selective adsorption of the silicon precursor on the first surface of the substrate, while minimizing or preventing adsorption of the silicon precursor on the second surface of the substrate. Typical pulse times range from about 0.1 second up to about 30 seconds, or from about 1 second to about 10 seconds, or from about 1 second to about 5 seconds, after which the reaction space may be flushed or purged to remove unreacted precursors, pretreatment agent, gaseous reaction by-products, and/or other species, as applicable.

Next, the substrate is exposed to a nitrogen precursor that is formed in a remote plasma (i.e., a plasma that is physically separated from the substrate). In the remote plasma, certain species may be promoted to an excited state, which may increase their reactivity with certain surface sites on the substrate; however, because of the physical separation of the plasma from the substrate, interactions of unwanted plasma species (e.g., electrons, ions, and photons) with the substrate surfaces may be minimized or even eliminated. Thus, the substrate is exposed to a nitrogen precursor that is formed or otherwise present in a remote plasma but it is not exposed, or not substantially exposed, to ions and electrons. In some instances, exposing the substrate to ions and electrons may result in the loss of the selectivity. A number of plasma discharge/reactor configurations may be employed to provide the remote plasma. For instance, in some embodiments, the plasma discharge may be provided in the upper part of a reaction chamber, where an ion trap separates the plasma in a “plasma zone” from the lower part of the reaction chamber where the substrate is located (the “reaction zone”). In other embodiments, a plasma discharge may be provided upstream of a reaction chamber using a remote plasma unit (RPU).

The remote plasma is generated from a reactive gas comprising a nitrogen compound and a nitrogen precursor is formed in or otherwise present in the plasma discharge. In some embodiments, the reactive gas comprises one or more of nitrogen (N₂), ammonia (NH₃), an alkyl amine, hydrazine (N₂H₂), and a substituted hydrazine; hence, the remote plasma may comprise one or more of nitrogen (N₂), ammonia (NH₃), an alkyl amine, hydrazine (N₂H₂), a substituted hydrazine, as applicable, as well as excited species, radical species, and plasma species formed therefrom. In some embodiments, the nitrogen precursor comprises a nitrogen plasma species, for example, the nitrogen precursor may comprise one or more of activated nitrogen (N₂), activated ammonia (NH₃), nitrogen atoms (N), NH and NH₂ radicals, and other N—H containing species created in the remote plasma. In some embodiments, the nitrogen precursor is a nitrogen plasma species, for example, the nitrogen precursor may be one or more of activated nitrogen (N₂), activated ammonia (NH₃), nitrogen atoms (N), NH and NH₂ radicals, and other N—H containing species created in the remote plasma. Preferably, the nitrogen precursor is free of ions and electrons; in other words, the nitrogen precursor does not comprise, or does not substantially comprise, ions and electrons. In some embodiments, the reactive gas, may further comprise hydrogen (H₂). In some embodiments, the reactive gas may comprise N₂ and H₂, where the N₂ and H₂ are provided at a flow ratio (N₂/H₂) from about 20:1 to about 1:20, or from about 10:1 to about 1:10, or from about 5:1 to about 1:5, or from about 1:2 to about 2:1, or in some cases about 1:1. In some embodiments, the reactive gas, may further comprise one or more of hydrogen (H₂), methane (CH₃), and oxygen (O₂). The reactive gas may optionally be mixed or co-fed with a carrier gas. The carrier gas may be a noble gas selected from the group consisting of helium (He), neon (Ne), argon (Ar), krypton (Kr), xenon (Xe), and mixtures thereof. The excited species from noble gases in the remote plasma do not necessarily contribute material to the deposited film but can, in some circumstances, contribute to film growth as well as help in the formation and ignition of the plasma.

The remote plasma may be produced by gas-phase ionization of a gas using a plasma generator, for example, a radio frequency (RF) (e.g., 13.56 MHz or 27 MHz) power generator or a microwave power generator. In some embodiments, the reactive gas may be fed into a reaction chamber through the plasma source and the plasma source is pulsed (turned on and off) to generate the remote plasma. The duration of the plasma pulse should be sufficiently long such that the adsorbed silicon precursor is substantially or completely transformed into the material comprising silicon and nitrogen. Typical exposure or pulse times range from about 0.1 second up to about 30 seconds, or from about 1 second to about 10 seconds, or from about 1 second to about 5 seconds, after which the reaction chamber may be flushed or purged to remove any unreacted reactive gas, gaseous reaction by-products, and other species. The power for generating the remote plasma can be varied in different embodiments of the disclosure. In some embodiments, the power for generating the remote plasma is typically from about 10 W to about 2,000 W, or from about 10 W to about 1,500 W, or from about 20 W to about 1,000 W, or from about 20 W to about 900 W, or from about 20 W to about 800 W, or from about 20 W to about 700 W, or from about 20 W to about 600 W, or from about 20 W to about 500 W, or from about 20 W to about 400 W, or from about 20 W to about 300 W, or from about 20 W to about 200 W, or from about 20 W to about 100 W, or any intermediate range of powers between about 10 W and about 2,000 W. In some embodiments, the power for generating the remote plasma may be maintained at about 25 W, or at about 50 W, or at about 75 W, or at about 100 W, or at about 125 W, or at about 150 W, or at about 175 W, or at about 200 W, or at about 225 W, or at about 250 W, or at about 275 W, or at about 300 W, or at about 325 W, or at about 350 W, or at about 375 W, or at about 400 W, or at about 425 W, or at about 450 W, or at about 475 W, or at about 500 W, or at about 525 W, or at about 550 W, or at about 575 W, or at about 600 W, or at about 625 W, or at about 650 W, or at about 675 W, or at about 700 W, or at about 725 W, or at about 750 W, or at about 775 W, or at about 800 W, or at about 825 W, or at about 850 W, or at about 875 W, or at about 900 W, or at about 925 W, or at about 950 W, or at about 975 W, or at about 1,000 W, or at about 1,050 W, or at about 1,100 W, or at about 1,150 W, or at about 1,200 W, or at about 1,250 W, or at about 1,300 W, or at about 1,350 W, or at about 1,400 W, or at about 1,450 W, or at about 1,500 W, or at about 1,550 W or at about 1,600 W, or at about 1,650 W, or at about 1,700 W, or at about 1,750 W, or at about 1,800 W, or at about 1,850 W, or at about 1,900 W, or at about 1,950 W, or at about 2,000 W.

In some embodiments, the method further comprises purging the reaction space between the various process steps. In some embodiments, the reaction space may be purged after each half cycle, and/or after each cycle, or periodically to remove unreacted reactants (e.g., precursors and/or reactive gases) and gas-phase reaction by-products from the surface(s) of the substrate. Optional purging steps are shown in FIG. 1. In other embodiments, the reaction space may be purged after the pretreatment step, each half cycle, and/or each cycle, or periodically to remove unreacted reactants (e.g., precursors, pretreatment agents, and/or reactive gases) and gas-phase reaction by-products from the surface(s) of the substrate. Optional purging steps are shown in FIG. 2 and FIG. 3. Purging may be affected, for example, by evacuating the reaction space with a vacuum pump and/or by replacing the gas inside the reaction space with an inert, or substantially inert, gas such as argon or nitrogen. In some instances, a purging step may be implemented between two pulses of gases which react with each other, or, in other instances, purging may be implemented between two pulses of gases that do not react with each other. Purging may avoid, or at least reduce, gas-phase interactions between two gases reacting with each other. It shall be understood that a purge can be affected either in time or in space, or both. For example, in the case of temporal purges, a purge step can be used in the temporal sequence of providing a first reactant to a reaction space, providing an inert gas to the reaction chamber and/or evacuating the reaction chamber, and then providing a second reactant gas to the reaction space, and so forth as applicable, wherein the substrate on which a material is deposited does not move. For example, in the case of spatial purges, a purge step can involve moving a substrate from a first location (e.g., a first reaction chamber) to which a first reactant is continually supplied, through a purge gas curtain, to a second location (e.g., a second reaction chamber) to which a second reactive gas is continually supplied, and so forth as applicable.

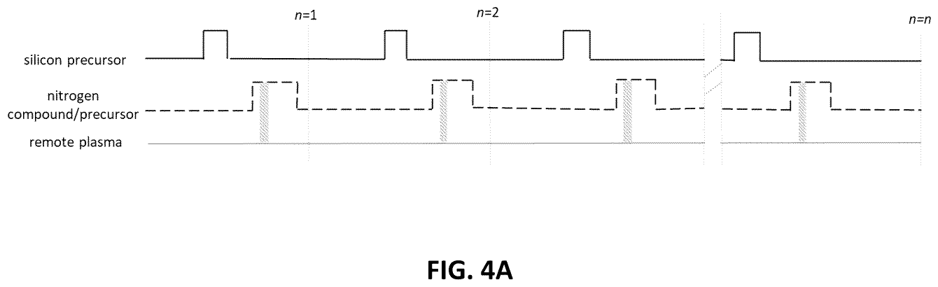

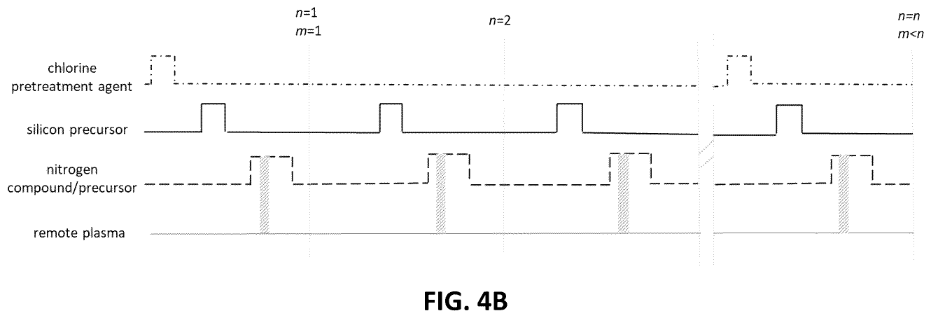

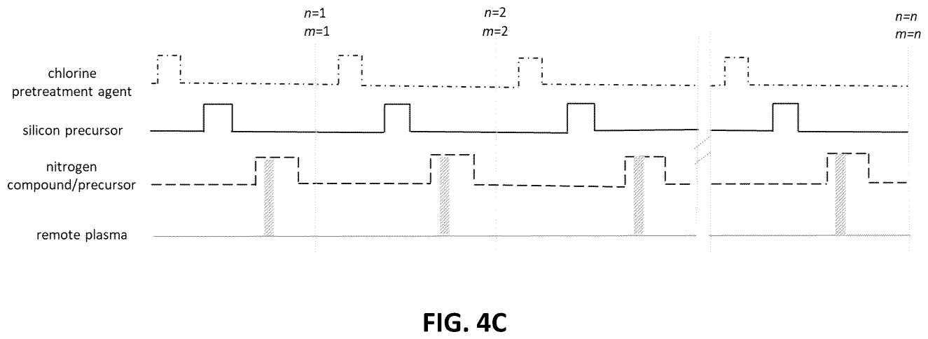

The various process steps may be repeated one or more times to grow a film of a material comprising silicon and nitrogen having a target thickness on the first surface of the substrate. As an example, referring to the embodiment shown in FIG. 1, the method may comprise repeating steps 101 and 103 one or more (n) times 106 to form a film of the material comprising silicon and nitrogen having a targeted thickness on the first surface of the substrate; or repeating steps 101, 102, 103, and 104 one or more (n) time 106 to form a film of the material comprising silicon and nitrogen having a targeted thickness on the first surface of the substrate; or repeating steps 101, 102, and 103 or steps 101, 103, and 104 one or more (n) time 106 to form a film of the material comprising silicon and nitrogen having a targeted thickness on the first surface of the substrate; or any combinations thereof. In some of these embodiments, the method may consist of repeating steps 101 and 103 one or more (n) times 106 to form a film of the material comprising silicon and nitrogen having a targeted thickness on the first surface of the substrate; or repeating steps 101, 102, 103, and 104 one or more (n) time 106 to form a film of the material comprising silicon and nitrogen having a targeted thickness on the first surface of the substrate; or repeating steps 101, 102, and 103 or steps 101, 103, and 104 one or more (n) time 106 to form a film of the material comprising silicon and nitrogen having a targeted thickness on the first surface of the substrate; or any combinations thereof. FIG. 4A shows an example of pulse sequences for the silicon precursor 101 and the nitrogen compound or precursor and remote plasma discharge 103 (other pulse sequences are possible). In another example, referring to the embodiment shown in FIG. 2, the method may comprise repeating steps 203 and 205 one or more (n) times 208 to form a film of the material comprising silicon and nitrogen having a targeted thickness on the first surface of the substrate; or repeating steps 203, 204, 205, and 206 one or more (n) time 208 to form a film of the material comprising silicon and nitrogen having a targeted thickness on the first surface of the substrate; or repeating steps 203, 204, and 205 or steps 203, 205, and 206 one or more (n) time 208 to form a film of the material comprising silicon and nitrogen having a targeted thickness on the first surface of the substrate; or any combinations thereof. In any of these sequences, the pretreatment step 201, or steps 201 and 202, may optionally be performed prior to step 203 and may be repeated one or more (m) times, intermittently (m n) or with every cycle (m n). FIG. 4B and FIG. 4C show example embodiments of pulse sequences for the chlorine pretreatment agent 201, the silicon precursor 203, and the nitrogen compound or precursor and remote plasma discharge 205, where m n and m n, respectively (other pulse sequences are possible). In yet another example, referring to the embodiment shown in FIG. 3, the method may comprise repeating steps 303 and 305 one or more (n) times 308 to form a film of the material comprising silicon and nitrogen having a targeted thickness on the first surface of the substrate; or repeating steps 303, 304, 305, and 306 one or more (n) times 308 to form a film of the material comprising silicon and nitrogen having a targeted thickness on the first surface of the substrate; or repeating steps 303, 304, and 305 or steps 303, 305, and 306 one or more (n) times 308 to form a film of the material comprising silicon and nitrogen having a targeted thickness on the first surface of the substrate; or any combinations thereof. In any of these sequences, the pretreatment step 301, or steps 301 and 302, is performed at least once prior to step 303 and may optionally be repeated one or more (m) times, intermittently (m n) or with every cycle (m n). FIG. 4B and FIG. 4C show example embodiments of pulse sequences for the chlorine pretreatment agent 301, the silicon precursor 303, and the nitrogen compound or precursor and remote plasma discharge 305, where m n and m n, respectively (other pulse sequences are possible). In any of these embodiments, other steps may be inserted in the process as needed. For example, one or more half cycles may independently be repeated. The substrate may be exposed to two or more pulses of the silicon precursor, then exposed to the nitrogen precursor; or conversely, the substrate may be exposed to the two or more pulses of the nitrogen precursor, then exposed to the silicon precursor. Other reaction steps, activation steps, passivation steps, curing steps, and/or cleaning steps may be performed between the various steps or before or after the various steps.

The number of repeated cycles (n) is not particularly limited and depends on the growth per-cycle (GPC) rate of the material comprising silicon and nitrogen on the first surface of the substrate (“first GPC rate”) and the targeted thickness of the film, as well as the GPC rate of the material comprising silicon and nitrogen on the second surface of the substrate (“second GPC rate”). The second GPC rate is small compared to the first GPC rate; however, as n becomes large, in some instances, some growth may occur on the second surface of the substrate. The number of repeated cycles (n) may be between 1 and about 2,000, or between 1 and about 1,500, or between 1 and about 1,000, or between 1 and about 500, or between 1 and about 200, or between 1 and about 100, or between about 10 and about 1,000, or between about 10 and about 500, or between about 10 and about 200, or between about 10 and about 100, or between about 50 and about 1,000, or between about 50 and about 500, or between about 50 and about 200. The pretreatment step, if present, may optionally be repeated m times, intermittently (m n) or prior to every cycle (m n). The number of repeated pretreatment steps (m) may be equal to or less than the number of repeated cycles (n), typically m is about n/2, or about n/5, or about n/10, or about n/25.

The methods disclosed herein may be performed at an elevated temperature. For instance, the substrate may be maintained at an elevated temperature. The temperature of the substrate may be optimized to tune or maximize the selective deposition process. Without limiting the disclosed methods to any specific theory, surface passivation may be more efficient at higher temperatures; however, at too high of a temperature, the selectivity may be lost. In some instances, the selectivity of the deposition process may be improved at lower temperatures. The temperature of the substrate should be selected to balance these factors. In some embodiments, the selective deposition process may be performed by maintaining the substrate temperature from about 40° C. to about 800° C., typically from about 75° C. to about 700° C., or from about 75° C. to about 750° C., or from about 75° C. to about 600° C., or from about 75° C. to about 650° C., or from about 75° C. to about 500° C., or from about 75° C. to about 450° C., or from about 75° C. to about 425° C., or from about 75° C. to about 400° C., or from about 100° C. to about 450° C., or from about 100° C. to about 425° C., or from about 100° C. to about 400° C., or from about 100° C. to about 375° C., or from about 100° C. to about 350° C., or from about 100° C. to about 325° C., or from about 100° C. to about 300° C., or any intermediate range of temperatures between about 40° C. and about 800° C. In some embodiments, the selective deposition process may be performed by maintaining the substrate temperature at about 50° C., or at about 75° C., or at about 100° C., or at about 125° C., or at about 150° C., or at about 175° C., or at about 200° C., or at about 225° C., or at about 250° C., or at about 275° C., or at about 300° C., or at about 325° C., or at about 350° C., or at about 375° C., or at about 400° C., or at about 425° C., or at about 450° C., or at about 475° C., or at about 500° C., or at about 525° C., or at about 550° C., or at about 575° C., or at about 600° C., or at about 625° C., or at about 650° C., or at about 675° C., or at about 700° C. In other embodiments, the selective deposition process may be performed at ambient temperature. In some embodiments, ambient temperature is room temperature (RT). In some embodiments, ambient temperature may vary between about 20° C. and about 30° C. In some embodiments, the selective process may be performed by maintaining the substrate temperature at a constant temperature. In some embodiments, the selective deposition process may be performed by maintaining the substrate temperature at a first temperature during the pretreatment step and at a second temperature during the ALD cycle. For example, a first temperature of the substrate during the pretreatment step may be higher than a second temperature of the substrate during the ALD cycle.

The methods disclosed herein may be performed at reduced pressure. In some embodiments, the pressure within the reaction space during the selective deposition process is less than about 500 Torr, typically from about 0.1 Torr to about 500 Torr, or from about 0.5 Torr to about 100 Torr, or from about 0.5 Torr to about 50 Torr, or from about 1 Torr to about 20 Torr. In some embodiments, the pressure within reaction space during the selective deposition process is less than about 100 Torr, or less than about 50 Torr, or less than about 20 Torr, or less than about 10 Torr. In some embodiments, the pressure during an ALD cycle is lower than about 20 Torr. In some embodiments, the pressure during an ALD cycle is lower than about 10 Torr. In some embodiments, the pressure during an ALD cycle is higher than about 1 Torr. In some embodiments, the pressure during an ALD cycle is higher than about 5 Torr. In some embodiments, the pressure during an ALD cycle is between about 1 Torr and about 25 Torr. In some embodiments, the selective deposition process may be performed at constant pressure. In some instances, a first pressure within the reaction space during the first half cycle may be the same or substantially the same as a second pressure in the reaction space during the second half cycle. In other embodiments, the pressure in the reaction space during the first half cycle is different than the pressure inside the reaction space during the second half cycle. For example, a first pressure in the reaction space during the first half cycle may be higher than a second pressure in the reaction space during the second half cycle. Alternatively, a first pressure in the reaction space during the first half cycle may be lower than a second pressure in the reaction space during the second half cycle. The pressure in the reaction space during the pretreatment step, if utilized, may also be different than the pressure inside the reaction space during the ALD cycle. For example, a pressure in the reaction space during the pretreatment step may be higher than a pressure in the reaction space during the ALD cycle. Alternatively, a pressure in the reaction space during the pretreatment step may be lower than a pressure in the reaction space during the ALD cycle. Alternatively, a pressure in the reaction space during the pretreatment step may be the same or substantially the same as a pressure in the reaction space during the ALD cycle. One of skill in the art will readily understand that the pressure within the reaction space may be independently selected for the pretreatment step, the first half cycle, the second half cycle, and any other process steps, to optimize the selective deposition process. Without limiting the disclosed method to any specific theory, in some embodiments, increasing the process pressure may increase the film growth rate and improve the film properties, thus reducing the necessary cycle time and/or cycle number to obtain the desired film properties and film thickness. These improvements may be attributed to changes in the surface saturation level, the enhancement of precursor diffusion, as well as the higher probability for surface reactions to occur at the active sites on the surface(s).

Another aspect of the disclosure relates to systems, for example a semiconductor apparatus, for depositing a material comprising silicon and nitrogen on a first surface of a substrate more so than on a second surface of the substrate using the methods described herein. The semiconductor processing apparatus comprises a reaction space (i.e., at least one reaction chamber) for accommodating a substrate comprising a first surface and a second surface and a means for forming a remote plasma. In some embodiments, the semiconductor processing apparatus may have one reaction chamber, two reaction chambers, three reaction chambers, four reaction chambers, or more. The semiconductor processing apparatus further comprises a means for exposing the substrate to a source of chlorine and a source of silicon, then exposing the substrate source of nitrogen. For example, the semiconductor processing apparatus comprises a means for sequentially exposing the substrate to a chlorine pretreatment agent, if utilized, a silicon precursor, and a nitrogen precursor that is formed in or otherwise present in a remote plasma. These elements are described above.

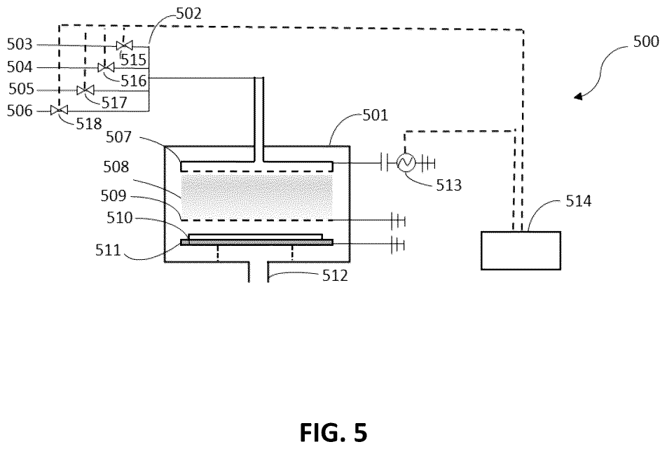

FIG. 5 shows an exemplary embodiment of a semiconductor processing apparatus 500 according to the present disclosure. Gaseous reactants are provided into a reaction chamber 501 through a gas manifold 502. The gas manifold may be configured to provide a silicon precursor from a first source 503, a reactive gas comprising a nitrogen compound from second source 504, and optionally a chlorine pretreatment agent from a third source 505. One or more of the gaseous reactants may be entrained in a carrier gas (e.g., nitrogen and/or a noble gas, such as He, Ne, Ar, Kr, Xe, and combinations thereof) provided from a fourth source 506. The various gasses flow through a showerhead 507 that is positioned directly above a susceptor 511 on which the substrate 510 is placed. The apparatus may also be configured to allow for the introduction of other gasses (e.g., reactive gasses, carrier gasses, and/or purging gasses), either through the shower head 507 or from other ports (not shown) into the reaction chamber 501. Unreacted gasses and gaseous reaction by-products exit the reaction chamber 501 through an exhaust line 512. The reaction chamber 501 may optionally be equipped with a purge line and/or a pump line coupled to a vacuum pump so that the reaction chamber may be purged between the various reaction cycles (not shown). A plasma generator 513 (e.g., a RF power generator or microwave power generator) is electrically connected to the showerhead 507, allowing for the showerhead to be biased relative to the susceptor 511 to form a plasma discharge between the two. Optionally, an ion trap 509 may be positioned between the showerhead 507 and the substrate 510 to restrict the plasma 508 to the upper portion of the reaction chamber, above the ion trap. For example, an electrically grounded mesh plate may be used as an ion trap. In some embodiments, the mesh plate is a metal plate comprising hundreds of holes in a showerhead-like pattern that lets radical species pass through to the substrate 510 while trapping the ions. The addition of the ion trap, beneficially reduces, or even eliminates, interactions of ions and electrons with the substrate surface(s) by restricting the plasma to the plasma zone 508 in the upper portion of the reaction chamber 501. The plasma generator 513, showerhead 507, susceptor 511, and optional ion trap 509 collectively make up a remote plasma unit, which may comprise other elements that are not shown here. The semiconductor processing apparatus also comprises a controller 514 operably connected to the first, second, third, and fourth valves, 515-518, the plasma generator 513, and other components (not shown). The controller 514 is configured and programmed to independently control (e.g., turn on and off, etc.) the supply of the various gasses (e.g., the silicon precursor, the reactive gas comprising the nitrogen precursor, the chlorine pretreatment agent, carrier gasses and purging gasses, etc.) and the plasma generator 513, as required, to deposit a film of the material comprising silicon and nitrogen on the first surface of the substrate.

In some embodiments, the controller 514 is configured and programed to perform a first sequence and a second sequence, among other things. In the first sequence, the controller 514 opens valve 515 to flow the silicon precursor from the first source 503 into the reaction chamber 501 and, after a set period of time, the controller 514 closes the valve 515 to the first source 503. Next, in the second sequence, the controller 514 opens valve 516 to flow the reactive gas comprising the nitrogen compound/precursor from the second source 504 into the reaction chamber 501 and, after a set period of time, pulses (turn on, then off) the plasma generator 513. After another set period of time, the controller 514 closes the valve 516 to the second source 504. The controller 514 may be programed to repeat the first sequence and the second sequences (n times) to grow a film of the material comprising silicon and nitrogen on the first surface of the substrate 510. The controller 514 may further be programed to perform other process steps prior to the first sequence and/or between the first and the second sequences. For example, in some embodiments, the controller 514 may further be configured and programed to perform a third sequence, wherein the controller 514 opens valve 517 to flow the chlorine pretreatment agent from the third source 505 into the reaction chamber 501 and, after a set period of time, the controller 514 closes the valve 517 to the third source 505. The controller 514 may be programed to perform the third sequence prior to performing the first sequence and to repeat the third sequence (m times) prior to some (m n) or all (m n) of the repeating the first and the second sequences.

In some embodiments, the semiconductor processing apparatus, comprises: a reaction space for accommodating a substrate comprising a first surface and a second surface; a first source for providing a silicon precursor in gas communication via a first valve with the reaction space; a second source for providing a reactive gas in gas communication via a second valve with the reaction space; a plasma unit comprising a plasma generator and configured to provide a remote plasma; and a controller operably connected to the first valve, the second valve, and the plasma generator. The controller may be configured and programmed to control: supplying the silicon precursor into the reaction space, wherein the silicon precursor adsorbs on the first surface of the substrate more so than on the second surface of the substrate; and supplying the reactive gas into the reaction space and activating the plasma generator to form a nitrogen precursor, wherein the nitrogen precursor converts the adsorbed silicon precursor to a material comprising silicon and nitrogen. The controller may be programmed to repeat the various process steps n time to deposit a film of the material comprising silicon and nitrogen on the first surface of the substrate more so than on the second surface of the substrate.

In other embodiments, the semiconductor processing apparatus, comprises: a reaction space for accommodating a substrate comprising a first surface and a second surface; a first source for providing a silicon precursor in gas communication via a first valve with the reaction space; a second source for providing a reactive gas in gas communication via a second valve with the reaction space; a third source for providing a chlorine pretreatment agent in gas communication via a third valve with the reaction space; a plasma unit comprising a plasma generator and configured to provide a remote plasma; and a controller operably connected to the first valve, the second valve, the third valve, and the plasma generator. The controller is configured and programmed to control: supplying the chlorine pretreatment agent into the reaction space; supplying the silicon precursor into the reaction space, wherein the silicon precursor adsorbs on the first surface of the substrate more so than on the second surface of the substrate; and supplying the reactive gas into the reaction space and activating the plasma generator to form a nitrogen precursor, wherein the nitrogen precursor converts the adsorbed silicon precursor to a material comprising silicon and nitrogen. The controller may be programmed to repeat various process steps to deposit a film of the material comprising silicon and nitrogen on the first surface of the substrate more so than on the second surface of the substrate. For example, the controller may be programmed repeat the supplying of the chlorine pretreatment agent into the reaction space m times and to repeat the supplying of the silicon precursor and the supplying of the reactive gas into the reaction space and activating the plasma generator n times.

The disclosed methods and systems can beneficially provide for selective deposition of a material comprising silicon and nitrogen on a substrate. The selectivity can be expressed as a ratio of deposition on a first surface of a substrate to the deposition on a second surface of the substrate; or it may be expressed as percentage calculated by [(deposition on the first surface)−(deposition on the second surface)]/(deposition on the first surface). The amount of deposition can be measured in of a variety of ways. In some embodiments, the amount of deposition may be given as the measured thickness of the deposited material. In some embodiments, the amount of deposition may be given as the measured amount (e.g., mass or volume) of the deposited material. In embodiments, the material comprising silicon and nitrogen is selectively deposited on the first surface of a substrate more so than on the second surface of the substrate. In other words, the material comprising silicon and nitrogen is selectively deposited a substrate comprising a first surface and a second surface, wherein the deposition occurs on the first surface more so than on the second surface. In this context, when the material comprising silicon and nitrogen is selectively deposited on the first surface of the substrate more so than on the second surface of the substrate, one or more of a thickness ratio, a mass ratio, and/or a volume ratio of the deposited material comprising silicon and nitrogen on the first surface versus the second surface may be at least about 70:30, or at least about 75:25, or at least about 80:20, or at least about 85:15, or at least about 90:10, or at least about 95:5, or at least about 97:3, or at least about 98:2, or at least about 99:1, or at least about 99.5:0.5, or at least about 99.9:0.1. Preferably, the material comprising silicon and nitrogen is deposited on the first surface of the substrate but not, or substantially not, on the second surface of the substrate.

The substrate comprises a first surface and a second surface, wherein the two surfaces have different material properties which provides contrast such that the material comprising silicon and nitrogen may be selectively deposited on the first surface of the substrate relative to the second surface of the substrate. In other words, the first surface of the substrate comprises a first material and the second surface of the substrate comprises a second material, wherein the first material and the second material are chemically distinct and provide contrast for the selective deposition. In some embodiments, the first surface comprises a material comprising silicon and nitrogen and the material comprising silicon and nitrogen (i.e., another material or additional material comprising silicon and nitrogen) is selectively deposited on the first surface. For instance, the first surface may comprise silicon nitride and the material comprising silicon and nitrogen may be selectively deposited on the first surface. In some embodiments, the first surface comprises, consists essentially of, or consists of silicon nitride. In other embodiments, the first surface comprises a metal and the material comprising silicon and nitrogen is selectively deposited on the first surface. The metal may be transition metal. In yet other embodiments, the first surface comprises a metal oxide and the material comprising silicon and nitrogen is selectively deposited on the first surface. The metal oxide may be a transition metal oxide. In some embodiments, the metal oxide comprises a transition metal that is selected from group 4 of the periodic table of elements. In some embodiments, the first surface comprises hafnium oxide and/or zirconium oxide and the material comprising silicon and nitrogen is selectively deposited on the first surface. In some embodiments, the first surface comprises, consists essentially of, or consists of hafnium oxide. In some embodiments, the first surface comprises, consists essentially of, or consists of zirconium oxide.

The second surface of the substrate may be, or may be able to become, passivated so that the material comprising silicon and nitrogen is not, or not substantially, deposited on the second surface. In some embodiments, the second surface comprises a material comprising silicon. For instance, the second surface may comprise one or more of silicon, silicon oxide, and silicon carbide. In some embodiments, the second surface comprises, consists essentially of, or consists of silicon. The silicon surface may comprise surface oxidation or it may substantially be in elemental form. In some embodiments, the second surface comprises, consists essentially of, or consists of silicon oxide. In other embodiments, the second surface comprises a metal and may be referred to as a metallic surface. In some embodiments, the second surface comprises, consists essentially of, or consists of one or more metals. The metal may be a transition metal. The metal may be substantially or completely in elemental form. In some embodiments, second surface comprises a metal selected from a group consisting of copper (Cu), tungsten (W), ruthenium (Ru), cobalt (Co), aluminum (Al), molybdenum (Mo), niobium (Nb), nickel (Ni), manganese (Mn), iron (Fe), zinc (Zn), tantalum (Ta), titanium (Ti), and combinations thereof. In some embodiments, the metal or metallic surface comprises a transition metal selected from a group consisting of copper, tungsten, ruthenium, cobalt, and combinations thereof.

In some embodiments, the first surface is silicon nitride, and the second surface is selected from the group consisting of silicon, silicon oxide, a metal, and combinations thereof. In some embodiments, the first surface is silicon nitride, and the second surface is selected from the group consisting of silicon, silicon oxide, copper, tungsten, ruthenium, cobalt, aluminum, molybdenum, niobium, nickel, manganese, iron, zinc, tantalum, titanium, and combinations thereof. In some embodiments, the first surface is silicon nitride, and the second surface is selected from the group consisting of copper, tungsten, ruthenium, cobalt, and combinations thereof. In some embodiments, the first surface is silicon nitride, and the second surface is silicon oxide. In some embodiments, the first surface is a transition metal oxide, and the second surface is selected from the group consisting of silicon, silicon oxide, a metal, and combinations thereof. In some embodiments, the first surface is a transition metal oxide, and the second surface is selected from the group consisting of silicon, silicon oxide, copper, tungsten, ruthenium, cobalt, aluminum, molybdenum, niobium, nickel, manganese, iron, zinc, tantalum, titanium, and combinations thereof. In some embodiments, the first surface is hafnium oxide, and the second surface is selected from the group consisting of silicon, silicon oxide, a metal, and combinations thereof. In some embodiments, the first surface is hafnium oxide, and the second surface is selected from the group consisting of silicon, silicon oxide, copper, tungsten, ruthenium, cobalt, aluminum, molybdenum, niobium, nickel, manganese, iron, zinc, tantalum, titanium, and combinations thereof. In some embodiments, the first surface is hafnium oxide, and the second surface is selected from the group consisting of copper, tungsten, ruthenium, cobalt, and combinations thereof. In some embodiments, the first surface is hafnium oxide, and the second surface is silicon oxide. In some embodiments, the first surface is zirconium oxide, and the second surface is selected from the group consisting of silicon, silicon oxide, a metal, and combinations thereof. In some embodiments, the first surface is zirconium oxide, and the second surface is selected from the group consisting of silicon, silicon oxide, copper, tungsten, ruthenium, cobalt, aluminum, molybdenum, niobium, nickel, manganese, iron, zinc, tantalum, titanium, and combinations thereof. In some embodiments, the first surface is zirconium oxide, and the second surface is selected from the group consisting of copper, tungsten, ruthenium, cobalt, and combinations thereof. In some embodiments, the first surface is zirconium oxide, and the second surface is silicon oxide. In some embodiments, the first surface is ruthenium, and the second surface is selected from the group consisting of silicon, silicon oxide, copper, tungsten, cobalt, aluminum, molybdenum, niobium, nickel, manganese, iron, zinc, tantalum, titanium, and combinations thereof. In some embodiments, the first surface is ruthenium, and the second surface is selected from the group consisting of silicon, silicon oxide, copper, tungsten, cobalt, and combinations thereof.

In some embodiments, the material comprising silicon and nitrogen may be deposited on a silicon nitride surface more so than on a surface selected from the group consisting of silicon, silicon oxide, a metal, and combinations thereof. For example, the material comprising silicon and nitrogen may be selectively deposited a substrate comprising a silicon nitride surface and one or more of a silicon surface, silicon oxide surface, and a metal surface, wherein the deposition occurs on the silicon nitride surface but not, or not substantially, on the one or more of the silicon surface, silicon oxide surface, and the metal surface. In some embodiments, the material comprising silicon and nitrogen may be deposited on a silicon nitride surface more so than on a surface selected from the group consisting of silicon, silicon oxide, tungsten, copper, ruthenium, cobalt, and combinations thereof. For example, the material comprising silicon and nitrogen may be selectively deposited a substrate comprising a silicon nitride surface and one or more of a silicon surface, a silicon oxide surface, a tungsten surface, a copper surface, a ruthenium surface, and a cobalt surface, wherein the deposition occurs on the silicon nitride surface but not, or not substantially, on the one or more of a silicon surface, a silicon oxide surface, a tungsten surface, a copper surface, a ruthenium surface, and a cobalt surface. In a specific example, the material comprising silicon and nitrogen may be selectively deposited a substrate comprising a silicon nitride surface and a silicon oxide surface, wherein the deposition occurs on the silicon nitride surface but not, or not substantially, on the silicon oxide surface. In some embodiments, the material comprising silicon and nitrogen may be selectively deposited on a transition metal oxide surface more so than on a surface selected from the group consisting of silicon, silicon oxide, a metal, and combinations thereof. For example, the material comprising silicon and nitrogen may be selectively deposited a substrate comprising a transition metal oxide surface and one or more of a silicon surface, a silicon oxide surface, and a metal surface, wherein the deposition occurs on the transition metal oxide surface but not, or not substantially, on the one or more of the silicon surface, the silicon oxide surface, and the metal surface. In some embodiments, the material comprising silicon and nitrogen may be selectively deposited on a hafnium oxide surface more so than on a surface selected from the group consisting of silicon, silicon oxide, tungsten, copper, ruthenium, cobalt, and combinations thereof. For example, the material comprising silicon and nitrogen may be selectively deposited a substrate comprising a hafnium oxide surface and one or more of a silicon surface, a silicon oxide surface, a tungsten surface, a copper surface, a ruthenium surface, and a cobalt surface, wherein the deposition occurs on the hafnium oxide surface but not, or not substantially, on the one or more of the silicon surface, the silicon oxide surface, the tungsten surface, the copper surface, the ruthenium surface, and the cobalt surface. In a specific example, the material comprising silicon and nitrogen may be selectively deposited a substrate comprising a hafnium oxide surface and a silicon oxide surface, wherein the deposition occurs on the hafnium oxide surface but not, or not substantially, on the silicon oxide surface. In some embodiments, the material comprising silicon and nitrogen may be selectively deposited on a zirconium oxide surface more so than on a surface selected from the group consisting of silicon, silicon oxide, tungsten, copper, ruthenium, cobalt, and combinations thereof. For example, the material comprising silicon and nitrogen may be selectively deposited a substrate comprising a zirconium oxide surface and one or more of a silicon surface, a silicon oxide surface, a tungsten surface, a copper surface, a ruthenium surface, and a cobalt surface, wherein the deposition occurs on the zirconium oxide surface but not, or not substantially, on the one or more of the silicon surface, the silicon oxide surface, the tungsten surface, the copper surface, the ruthenium surface, and the cobalt surface. In a specific example, the material comprising silicon and nitrogen may be selectively deposited a substrate comprising a zirconium oxide surface and a silicon oxide surface, wherein the deposition occurs on the zirconium oxide surface but not, or not substantially, on the silicon oxide surface. In some embodiments, the material comprising silicon and nitrogen may be selectively deposited on a ruthenium surface more so than on a surface selected from the group consisting of silicon, silicon oxide, tungsten, copper, cobalt, and combinations thereof. For example, the material comprising silicon and nitrogen may be selectively deposited a substrate comprising a ruthenium surface and one or more of a silicon surface, a silicon oxide surface, a tungsten surface, a copper surface, and a cobalt surface, wherein the deposition occurs on the ruthenium surface but not, or not substantially, on the one or more of the silicon surface, the silicon oxide surface, the tungsten surface, the copper surface, and the cobalt surface.

The methods and systems disclosed herein can beneficially provide for the selective deposition of a material comprising silicon and nitrogen. In some embodiments, the methods and systems may also allow for selective deposition of a material comprising silicon and nitrogen using simple two-step cyclic deposition process (precursor/reactant gas or precursor/purge/reactant gas/purge) using a silicon precursor that comprises both silicon and chlorine, without the use of separate passivation and/or activation steps (i.e., pretreatment steps). In some embodiments, methods and systems allow for selective deposition of the material comprising silicon and nitrogen without the use of a separate passivation step and/or a separate activation step (i.e., pretreatment steps). Without wishing to be bound by a particular theory, certain silicon precursors comprising both silicon and chlorine may possess dual functionality, beneficially acting as an adsorbent on the first surface and a passivation agent towards the second surface.

### EXAMPLES

### Example 1: Selective Deposition of Silicon Nitride Using Alkyl Chlorosilane Precursors on Silicon Nitride Versus Silicon Oxide Surfaces

Deposition of silicon nitride was investigated on a silicon nitride surface and on a silicon oxide surface. For the silicon oxide surface, a native oxide terminated silicon wafer was used. For the silicon nitride surface, a silicon nitride film was grown on the surface of a 300 mm Si wafer at 390° C. and 5.2 Torr using a standard PE-ALD process with diiodosilane (SiH₂I₂) as the precursor. Specifically, the Si wafer was housed in a reaction chamber and exposed to sequential pulses of a) diiodosilane (SiH₂I₂) and b) a N₂/H₂/Ar/He remote plasma at 100 W for 12.5 seconds. The reaction chamber was purged between pulses. The process was repeated for roughly 100 cycles to yield a silicon nitride film having a thickness of about 1.5 nm.

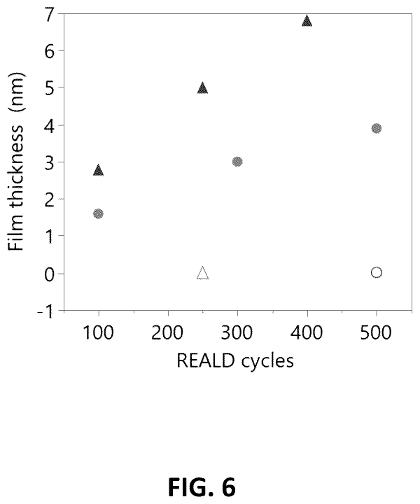

The silicon nitride surface, produced using the standard ALD process, was maintained at 390° C. and exposed to sequential pulses of a) bis(trichlorosilyl) methane or bis(trichlorosilyl) ethane and b) a N₂/H₂/Ar/He 100 W remote RF plasma at for 12.5 seconds at 5.2 Torr. The remote plasma discharge was provided in the upper portion of the reaction chamber and separated from the substrate surface by an electrically grounded mesh plate which acts as an ion trap, preventing ions and electrons from reaching the substrate surface. The reaction chamber was purged between pulses. FIG. 6 shows the growth of the deposited film on the silicon nitride surface using bis(trichlorosilyl) methane (▴) and bis(trichlorosilyl) ethane (•) precursors as a function of the number of ALD cycles (n). In both cases, the film thickness increases linearly with increasing cycle number. Use of the bis(trichlorosilyl) methane precursor leads to a higher GPC of the deposited film, which may be due to the smaller size of the precursor molecule. X-ray photoelectron spectroscopy (XPS) was used to identify the composition of the film grown using the bis(trichlorosilyl) methane precursor as silicon nitride having no measurable carbon content (see Table 1).

TABLE 1
Composition of film measured using XPS

| Element | Peak | Amount (%) |
|---|---|---|
| silicon | Si(2p) | 49.73 |
| nitrogen | N(1s) | 46.67 |
| oxygen | O(1s) | 2.95 |
| chlorine | Cl(2p) | 0.65 |

The silicon oxide surface was subjected to the same ALD process as the silicon nitride surface was. However, as shown in FIG. 6, essentially no growth was observed on the silicon oxide surface using bis(trichlorosilyl)methane (Δ) and bis(trichlorosilyl)ethane(∘) under the investigated conditions.

These results show that, using the disclose ALD method with bis(trichlorosilyl) methane and bis(trichlorosilyl) ethane as precursors, a silicon nitride film can be deposited on a silicon nitride surface but not on a silicon oxide surface. Thus, the difference in the reactivities of the surfaces can be exploited to yield selective deposition of a silicon nitride film on a substrate comprising both silicon nitride sites and silicon oxide sites. For example, silicon nitride may be selectively deposited a substrate comprising silicon nitride surface sites and silicon oxide surface sites, wherein the deposition occurs on the silicon nitride surface sites but not on the silicon oxide surface sites. Moreover, these results demonstrate that selective deposition of silicon nitride is possible using a simple two-step cyclic deposition method, without the use of separate passivation and/or activation steps (i.e., pre-treatment steps).

### Example 2: Selective Deposition of Silicon Nitride Using a Chlorosilane Precursor on Silicon Nitride Versus Silicon Oxide Surfaces

The experiments performed in Example 1 were repeated, except that octachlorotrisilane (Si₃Cl₈) was used as the silicon precursor and the silicon nitride substrate and the silicon oxide substrate were maintained at a temperature of 350° C. All other parameters were the same as those described in Example 1.

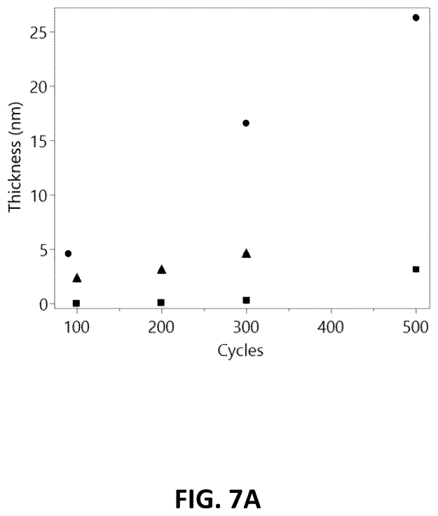

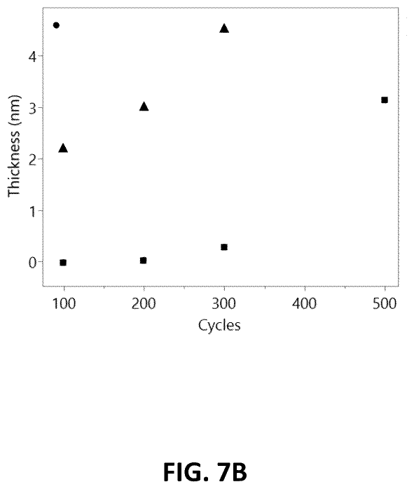

FIG. 7A shows the thickness of the silicon nitride film as a function of the number of ALD cycles (n); these results are enlarged in FIG. 7B. The triangle symbols (A) show the growth of a silicon nitride film on the silicon nitride surface. At about 100 cycles the silicon nitride film has a thickness of about 2.2 nm; the film thickness increases to about 3.0 nm at about 200 cycles and 4.5 nm at about 300 cycles. The square symbols (▪) show the growth of a silicon nitride film on the silicon oxide surface. Silicon nitride growth occurs on the silicon oxide surface but at a significantly lower level than on the silicon nitride surface. No substantial growth was observed on the silicon oxide surface at about 200 cycles and only minimal growth (about 0.3 nm) is observed at about 300 cycles; after 500 cycles the thickness of the silicon nitride film was about 3.1 nm on the silicon oxide surface.

These results show that silicon nitride film can preferentially be deposited on a silicon nitride surface versus a silicon oxide surface using the disclose ALD method with octachlorotrisilane as the precursor. Under the investigated conditions, the difference in the nucleation times on the two surfaces can be exploited to yield selective deposition of silicon nitride on a substrate comprising both silicon nitride surface sites and silicon oxide surface sites. As the number of ALD cycles increases, some silicon nitride growth was observed on the silicon oxide surface and this may limit the thickness of the silicon nitride film that may be selectively deposited on the silicon nitride surface. Nevertheless, the thickness that was obtained for the silicon nitride film on the silicon nitride surface before any significant deposition occurred on the silicon oxide surface, is likely sufficient for many applications and the ALD process can likely be optimized to improve the selectivity. Like Example 1, these results demonstrate that selective deposition of silicon nitride is possible using a simple two-step cyclic deposition method, without the use of separate passivation and/or activation steps (i.e., pre-treatment steps).

### Example 3: Deposition of Silicon Nitride Using a Chlorosilane Precursor on a Silicon Oxide Surface Using a Direct Plasma

As a comparison, a silicon nitride film was grown on the surface of a silicon oxide surface using a direct plasma, rather than a remote plasma. For the silicon oxide surface, a native oxide terminated silicon wafer was used. The silicon oxide film was exposed to sequential pulses of a) octachlorotrisilane and b) a N₂/H₂/Ar/He 150 W direct RF plasma at for 4 seconds at 5 torr and 350° C. The reaction chamber was purged between pulses. The film growth is shown in FIG. 7A by the circle symbols (•). X-ray photoelectron spectroscopy (XPS) was used to identify the composition of the film as silicon nitride (see Table 2). Compared to the analogous processes with the remote plasma (▪) in Example 2 (see FIG. 7A), significant silicon nitride growth is observed when using a direct plasma (•). These results show that silicon nitride growth on the silicon oxide surface is not inhibited when a direct plasma is used. Without limiting the disclosed methods to any particular theory, ionic species present in the direct plasma may convert the passivation layer, that was formed on the surface in the first half cycle, to a more reactive surface that facilitates silicon nitride growth. Once a silicon nitride layer, or sub-layer, has been formed, subsequent ALD cycles continue to the grow the silicon nitride film.

TABLE 2
Composition of film measured using XPS

| element | peak | Amount (%) |
|---|---|---|
| silicon | Si(2p) | 49.26 |
| nitrogen | N(1s) | 46.43 |
| oxygen | O(1s) | 3.48 |
| chlorine | Cl(2p) | 0.84 |

### Example 4: Deposition of Silicon Nitride Using a Chlorosilane Precursor on Various Surfaces

The experiments performed in Example 2 were repeated on a variety of substrates (tungsten (W), ruthenium (Ru), copper (Cu), hafnium oxide (HfO₂), and silicon oxide (SiO₂) (native oxide terminated and thermal oxide silicon)), each maintained at 350° C. in a reaction chamber. Specifically, each substrate was exposed to sequential pulses of a) octachlorotrisilane and b) a N₂/H₂/Ar/He 100 W remote RF plasma at for 12.5 seconds. The reaction chamber was purged between pulses.

The silicon content on each of the substrates was analyzed using XPS after 50 cycles and after 150 cycles of the ALD process; these results are summarized in Table 3. Deposition may be measured by comparing the difference in the Si(2p) signal at n=50 and n=150, where an increase in the signal is attributed to silicon nitride deposition. The change Si(2p) signal from n=50 to n=150 is small, within the statistical error of the measurement method, for the tungsten, copper, and silicon oxide surfaces; thus, the ALD process did not lead to any substantial silicon nitride deposition on these surfaces. A small increase in Si(2p) signal is observed on the ruthenium surface, indicating that some silicon nitride deposition occurred on the surface. A significant increase in the Si(2p) signal is observed on the hafnium oxide surface, which is attributed to silicon nitride deposition on the surface.

The differences in the reactivities of the various surfaces may be exploited to yield selective deposition of silicon nitride. For example, silicon nitride may selectively be deposited on a hafnium oxide surface versus a silicon oxide surface. This is further supported by film thickness measurements, obtained using spectroscopic ellipsometry data collected over wavelengths from 300 nm to 850 nm, provided in Table 4, which shows deposition on a hafnium oxide surface but no substantial deposition on the silicon oxide surfaces. No difference was observed for a native oxide terminated silicon surface versus a thermal oxide silicon surface. Any deposition on the silicon oxide surfaces is minimal. Thus, silicon nitride may be selectively deposited a substrate comprising hafnium oxide surface sites and silicon oxide surface sites, wherein deposition occurs on the hafnium oxide surface sites but not, or not substantially, on the silicon oxide surface sites.

TABLE 3
Area under peak (count*eV/s) for Si(2p) measured using XPS
after 50 cycles and after 150 cycles of the ALD process.

| Substrate | n = 50 | n = 150 |
|---|---|---|
| W | 210323 | 223079 |
| Ru | 192102 | 246295 |
| Cu | 258166 | 236926 |
| HfO₂ | 129040 | 554392 |
| SiO₂** | 108043 | 95381 |

**SiO₂ from native terminated oxide silicon.

TABLE 4
Film thick (nm) measure by ellipsometry after 50
cycles and after 150 cycles of the ALD process.

| Substrate | n = 50 | n = 150 |
|---|---|---|
| HfO₂ | 0.6 | 1.41 |
| SiO₂* | 0 | 0.27 |
| SiO₂** | 0 | 0.23 |

*SiO₂ from thermal oxide silicon.
**SiO₂ from native terminated oxide silicon.

Other examples of selective deposition are apparent from the data in Table 3. For example, silicon nitride may be selectively deposited on a substrate comprising a hafnium oxide surface and a tungsten surface, wherein the selective deposition occurs on the hafnium oxide surface sites but not on the tungsten surface sites. In another example, silicon nitride may be selectively deposited a substrate comprising a hafnium oxide surface and a copper surface, wherein the deposition occurs on the hafnium oxide surface but not on the copper surface. In another example, silicon nitride may be selectively deposited a substrate comprising a hafnium oxide surface and a ruthenium surface, wherein the deposition occurs on the hafnium oxide surface but not on the ruthenium surface. With process optimization, silicon nitride may be selectively deposited a substrate comprising a ruthenium surface and one or more of a silicon oxide surface, a tungsten surface, and a copper surface, wherein the deposition occurs on the ruthenium surface but not on the one or more of silicon oxide surface, tungsten surface, and copper surface.

Although certain embodiments and examples are disclosed herein, it will be understood by those skilled in the art that the disclosed methods and systems extend beyond the specifically disclosed embodiments and include all novel and nonobvious combinations and sub-combinations of the various methods, systems, and configurations, as well as any and all equivalents thereof. It is to be understood that the methods and/or systems described herein are exemplary in nature, and that these specific embodiments or examples are not to be considered in a limiting sense, because numerous variations are possible. The specific methods and systems described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The methods and systems of the disclosure are not to be interpreted as reflecting an intention that the claimed disclosure requires more features than are expressly recited in each claim. Rather, as the following claims reflect, inventive aspects lie in less than all features of a single foregoing disclosed aspects, embodiments, and configurations. Thus, the following claims are hereby incorporated into this Detailed Description, with each claim standing on its own as a separate embodiment of the disclosure, and the features recited in the various dependent claims may be combined with one another in various combinations, as appropriate, to form other embodiment of the disclosure.

The invention claimed is:

1. A method for selectively depositing a material comprising silicon and nitrogen on a substrate, the method comprising:
i. providing a substrate comprising a first surface and a second surface in a reaction space, wherein the first surface and the second surface are chemically distinct;
ii. exposing the substrate to a silicon precursor, wherein the silicon precursor adsorbs on the first surface of the substrate more so than on the second surface of the substrate;
iii. purging the reaction space;
iv. exposing the substrate to a nitrogen precursor formed in a remote plasma to convert the adsorbed silicon precursor to a material comprising silicon and nitrogen; and
V. purging the reaction space.

2. The method according to claim 1, wherein a ratio of the material comprising silicon and nitrogen deposited on the first surface of the substrate versus the second surface of the substrate is at least about 70:30.

3. The method according to claim 1, wherein a ratio of the material comprising silicon and nitrogen deposited on the first surface of the substrate versus the second surface of the substrate is at least about 90:10.

4. The method according to claim 1, wherein the material comprising silicon and nitrogen is deposited on the first surface of the substrate and not on the second surface of the substrate.

5. The method according to claim 1, wherein the method further comprises a pretreatment step comprising exposing the substrate to a chlorine pretreatment agent.

6. The method according to claim 1, wherein the method does not comprise a separate passivation pretreatment step and/or activation pretreatment step.

7. The method according to claim 1, further comprising:
repeating steps ii-v to grow a film of the material comprising silicon and nitrogen on the first surface of the substrate.

8. The method according to claim 1, wherein the material comprising silicon and nitrogen is selected from the group consisting of silicon nitride, silicon carbonitride, silicon oxynitride, silicon carbon oxynitride, and combinations thereof.

9. The method according to claim 1, wherein the first surface comprises silicon nitride and the second surface comprises one or more of silicon, silicon oxide, and a metal.

10. The method according to claim 9, wherein the second surface comprises silicon oxide.

11. The method according to claim 9, wherein the second surface comprises a metal selected from the group consisting of tungsten, copper, ruthenium, cobalt, and combinations thereof.

12. The method according to claim 1, wherein the first surface comprises a transition metal oxide and the second surface comprises one or more of silicon, silicon oxide, and a metal.

13. The method according to claim 12, wherein the first surface comprises hafnium oxide or zirconium oxide, and the second surface comprises silicon oxide.

14. The method according to claim 12, wherein the first surface comprises hafnium oxide or zirconium oxide, and the second surface comprises a metal selected from the group consisting of tungsten, copper, ruthenium, cobalt, and combinations thereof.

15. The method according to claim 1, wherein the silicon precursor comprises silicon and chlorine.

16. The method according to claim 15, wherein the silicon precursor is selected from the group consisting of a chlorosilane, an alkyl chlorosilane, and combinations thereof.

17. The method according to claim 16, wherein the silicon precursor is selected from the group consisting of dichlorosilane, tetrachlorosilane, hexachlorodisilane, octachlorotrisilane, bis(trichlorosilyl) methane, bis(trichlorosilyl) ethane, and combinations thereof.

18. The method according to claim 1, wherein the nitrogen precursor is selected from the group consisting of activated nitrogen, activated ammonia, nitrogen atoms, NH radicals, NH2 radicals, and combinations thereof.

19. The method according to claim 1, wherein the nitrogen precursor is a nitrogen plasma species that is free of ions and electrons.

20. A semiconductor processing apparatus, comprising:
a reaction space for accommodating a substrate comprising a first surface and a second surface, wherein the first surface and the second surface are chemically distinct;
a first source for providing a silicon precursor in gas communication via a first valve with the reaction space;
a second source for providing a reactive gas in gas communication via a second valve with the reaction space;
a remote plasma unit comprising a plasma generator; and
a controller operably connected to the first valve, the second valve, and the plasma generator, wherein the controller is configured and programmed to control:
supplying the silicon precursor into the reaction space, wherein the silicon precursor adsorbs on the first surface of the substrate more so than on the second surface of the substrate; and
supplying the reactive gas into the reaction space and activating the plasma generator to form a nitrogen precursor that is free of ions and electrons, wherein the nitrogen precursor converts the adsorbed silicon precursor to a material comprising silicon and nitrogen.
